(19) United States
(12) Patent Application Publication
(10) Pub. No.: US 2026/0057924 A1
(43) Pub. Date: Feb. 26, 2026

(54) SEMICONDUCTOR DEVICE AND METHOD FOR DRIVING THE SEMICONDUCTOR DEVICE

(71) Applicant: SEMICONDUCTOR ENERGY LABORATORY CO., LTD., Atsugi-shi, Kanagawa-ken (JP)

(72) Inventors: Hiroki INOUE, Atsugi, Kanagawa (JP); Takanori MATSUZAKI, Atsugi, Kanagawa (JP); Hidetomo KOBAYASHI, Isehara, Kanagawa (JP); Yuki OKAMOTO, Ebina, Kanagawa (JP)

(21) Appl. No.: 19/103,314

(22) PCT Filed: Aug. 17, 2023
(86) PCT No.: PCT/IB2023/058240

§ 371 Date: Feb. 12, 2025

(30) Foreign Application Priority Data
Aug. 30, 2022 (JP) 2022-137193

(51) Int. Cl. G11C 11/405; G11C 11/4091

(52) U.S. Cl. CPC G11C 11/405; G11C 11/4091

(57) ABSTRACT

A semiconductor device that is highly integrated and reliable is provided. A back gate electrode of a second transistor is electrically connected to a control signal line supplying a control signal controlling the threshold voltage of the second transistor. One of a source and a drain of the second transistor is electrically connected to a read word line supplying a read word signal. The other of the source and the drain of the second transistor is electrically connected to a read bit line reading a potential corresponding to data. In a memory cell selected in a data reading period, a low level is supplied as the read word signal and a high level is supplied as the control signal. In the memory cell not selected in the data reading period, a high level is supplied as the read word signal and a low level is supplied as the control signal.

### TECHNICAL FIELD

One embodiment of the present invention relates to a semiconductor device, a storage device, and an electronic device. Another embodiment of the present invention relates to a driving method for a semiconductor device.

Note that one embodiment of the present invention is not limited to the above technical field. Examples of the technical field of one embodiment of the present invention include a semiconductor device, a display device, a light-emitting device, a power storage device, a storage device, an electronic device, a lighting device, an input device (e.g., a touch sensor), an input/output device (e.g., a touch panel), a method for driving any of them, and a method of manufacturing any of them.

Note that in this specification and the like, a semiconductor device refers to a general device that can function by utilizing semiconductor characteristics. A semiconductor element such as a transistor, a semiconductor circuit, an arithmetic device, and a storage device are each one embodiment of a semiconductor device. It can sometimes be said that a display device (a liquid crystal display device, a light-emitting display device, and the like), a projection device, a lighting device, an electro-optical device, a power storage device, a storage device, a semiconductor circuit, an imaging device, an electronic device, and the like include a semiconductor device.

### BACKGROUND ART

In recent years, research and development have been actively conducted on a structure in which a plurality of dies (e.g., silicon dies) provided with circuits having different functions, such as SRAM cells or DRAM cells, are stacked three-dimensionally (e.g., Non-Patent Document 1 and Non-Patent Document 2).

Moreover, in recent years, technical development of a semiconductor device capable of retaining electric charge corresponding to data with the use of a transistor using an oxide semiconductor in its channel formation region (hereinafter an OS transistor) has progressed (e.g., Patent Document 1). A layer including OS transistors can be stacked over a die including transistors using silicon in their channel formation regions (hereinafter Si transistors). Patent Document 2 discloses a structure in which a plurality of layers including OS transistors are stacked three-dimensionally over a die including Si transistors.

### REFERENCES

### Patent Documents

[Patent Document 1] Japanese Published Patent Application No. 2011-119675

[Patent Document 2] PCT International Publication No. 2020/152522

### Non-Patent Documents

[Non-Patent Document 1] W. Gomes et al., ISSCC Dig. Tech. Papers, pp. 42-43, 2022.

[Non-Patent Document 2] M. Park et al., ISSCC Dig. Tech. Papers, pp. 444-445, 2022.

### SUMMARY OF THE INVENTION

### Problems to be Solved by the Invention

In the case of a NOSRAM (Nonvolatile Oxide Semiconductor Random Access Memory) using an OS transistor disclosed in Patent Document 1, the memory cell has a two-transistor (2T) or three-transistor (3T) structure. In the semiconductor device, the number of elements such as transistors and capacitors per memory cell is preferably small in order to increase the memory density.

In a two-transistor memory cell using a OS transistor, at the time of data reading operation, a current flowing through the transistor for data reading needs to be controlled by supplying a signal to one electrode of a capacitor included in the memory cell so that the memory cell performs different operations when selected and non-selected. However, a malfunction might occur owing to a variation in the potential of a bit line for data reading, for example. Thus, the reliability of data to be read might be degraded.

An object of one embodiment of the present invention is to provide a semiconductor device or the like having excellent data reliability. Another object of one embodiment of the present invention is to provide a semiconductor device or the like that is excellent in reducing power consumption. Another object of one embodiment of the present invention is to provide a semiconductor device or the like that is excellent in increasing the memory density. Another object of one embodiment of the present invention is to provide a novel semiconductor device or the like.

Note that the objects of one embodiment of the present invention are not limited to the objects listed above. The objects listed above do not preclude the presence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device including a memory cell including a first transistor and a second transistor. The first transistor includes a gate electrode. The second transistor includes a gate electrode and a back gate electrode. The gate electrode of the first transistor is electrically connected to a write word line supplying a write word signal. One of a source and a drain of the first transistor is electrically connected to a write bit line writing a potential corresponding to data. The other of the source and the drain of the first transistor is electrically connected to the gate electrode of the second transistor. The back gate electrode of the second transistor is electrically connected to a control signal line supplying a control signal controlling a threshold voltage of the second transistor. One of a source and a drain of the second transistor is electrically connected to a read word line supplying a read word signal. The other of the source and the drain of the second transistor is electrically connected to a read bit line reading the potential corresponding to data. In the memory cell selected in a data reading period, a low level is supplied as the read word signal and a high level is supplied as the control signal. In the memory cell not selected in the data reading period, a high level is supplied as the read word signal and a low level is supplied as the control signal.

In the semiconductor device of one embodiment of the present invention, each of the first transistor and the second transistor is preferably an n-channel transistor.

In the semiconductor device of one embodiment of the present invention, it is preferable that each of the first transistor and the second transistor include a semiconductor layer including a channel formation region and the semiconductor layer include an oxide semiconductor.

In the semiconductor device of one embodiment of the present invention, the oxide semiconductor preferably includes In, Ga, and Zn.

One embodiment of the present invention is a method for driving a semiconductor device including a memory cell array provided with a memory cell. The memory cell includes a first transistor in which a gate electrode is electrically connected to a write word line supplying a write word signal and one of a source and a drain is electrically connected to a write bit line writing a potential corresponding to data. The memory cell includes a second transistor in which a gate electrode is electrically connected to the other of the source and the drain of the first transistor, a back gate electrode is electrically connected to a control signal line supplying a control signal controlling a threshold voltage of the second transistor, one of a source and a drain is electrically connected to a read word line supplying a read word signal, and the other of the source and the drain is electrically connected to a read bit line reading the potential corresponding to the data. In a data reading period, in the memory cell selected, the read word signal is set to a low level and the control signal is set to a high level, and in the memory cell not selected, the read word signal is set to a high level and the control signal is set to a low level.

Note that other embodiments of the present invention will be described in the following embodiments with reference to the drawings.

### Effect of the Invention

According to one embodiment of the present invention, a semiconductor device or the like having excellent data reliability can be provided. According to one embodiment of the present invention, a semiconductor device or the like that is excellent in reducing power consumption can be provided. According to one embodiment of the present invention, a semiconductor device or the like that is excellent in increasing the memory density can be provided. One embodiment of the present invention can provide a novel semiconductor device or the like.

Note that the description of these effects does not preclude the existence of other effects. Note that one embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1C are diagrams illustrating a structure example of a semiconductor device and a timing chart.

FIG. 2A and FIG. 2B are diagrams illustrating a structure example of a semiconductor device.

FIG. 3A and FIG. 3B are diagrams illustrating a semiconductor device.

FIG. 4A and FIG. 4B are diagrams illustrating a semiconductor device.

FIG. 5A and FIG. 5B are diagrams illustrating a semiconductor device.

FIG. 6A to FIG. 6E are diagrams each illustrating a structure example of a semiconductor device.

FIG. 7A and FIG. 7B are diagrams illustrating a structure example of a semiconductor device and timing charts.

FIG. 8A and FIG. 8B are diagrams illustrating a structure example of a semiconductor device.

FIG. 9 is a diagram illustrating a structure example of a semiconductor device.

FIG. 10A to FIG. 10C are diagrams illustrating a structure example of a semiconductor device.

FIG. 11 is a diagram illustrating a structure example of a semiconductor device.

FIG. 12A to FIG. 12D are diagrams illustrating a structure example of a semiconductor device.

FIG. 13 is a diagram illustrating a structure example of a semiconductor device.

FIG. 14A and FIG. 14B are diagrams illustrating a structure example of a semiconductor device.

FIG. 15A and FIG. 15B are diagrams each illustrating an example of an electronic component.

FIG. 16A and FIG. 16B are diagrams each illustrating an example of an electronic device, and FIG. 16C to FIG. 16E are diagrams illustrating an example of a large computer.

FIG. 17 is a diagram illustrating an example of a device for space.

FIG. 18 is a diagram illustrating an example of a storage system that can be used in a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of the embodiments below.

In the drawings, the size, the layer thickness, or the region is exaggerated for clarity in some cases. Therefore, they are not limited to the illustrated scale. Note that the drawings schematically illustrate ideal examples, and embodiments of the present invention are not limited to shapes, values, and the like illustrated in the drawings.

Unless otherwise specified, off-state current in this specification and the like refers to drain current of a transistor in an off state (also referred to as a non-conducting state or a cutoff state). Unless otherwise specified, an off state in an n-channel transistor refers to a state where voltage V_{gs} between its gate and source is lower than threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, an OS transistor can also be referred to as a transistor including a metal oxide or an oxide semiconductor.

### Embodiment 1

In this embodiment, a semiconductor device of one embodiment of the present invention and a driving method thereof will be described. The semiconductor device described in this embodiment includes a plurality of memory cells and has a function of a memory cell array in which data retained in each memory cell is written and read.

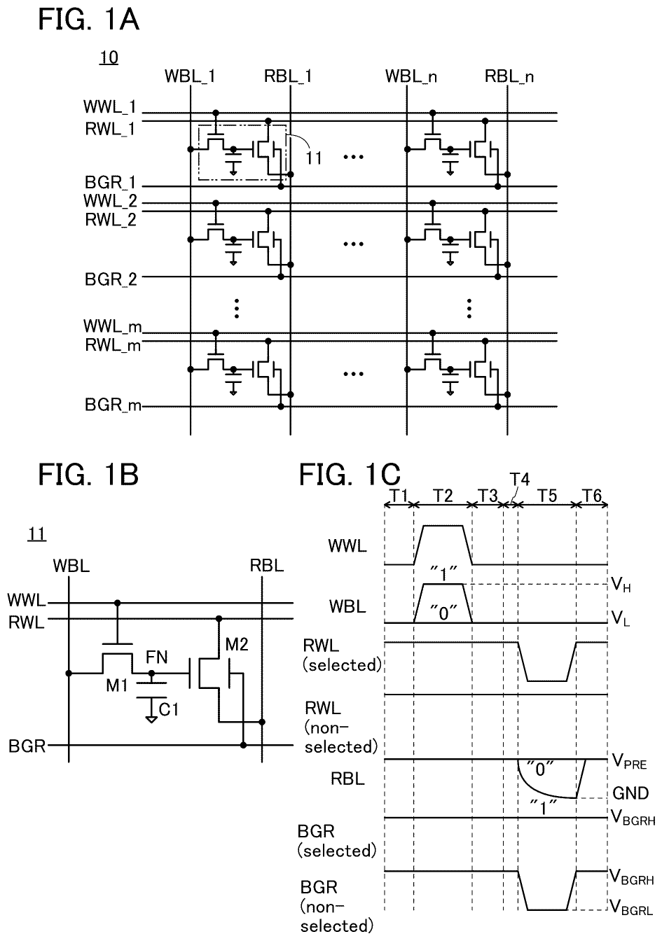

FIG. 1A illustrates a memory cell array 10 in which memory cells 11 are arranged in a matrix of m rows and n columns. FIG. 1B is a circuit diagram for illustrating a structure example of the memory cell 11 in FIG. 1A. FIG. 1C is a timing chart for describing an operation of the memory cell 11.

Note that in the memory cell array 10 having a matrix of m rows and n columns, a given row is referred to as an i-th row in some cases. In addition, a given column is denoted as a j-th column in some cases. Thus, i is an integer greater than or equal to 1 and less than or equal to m, and j is an integer greater than or equal to 1 and less than or equal to n. In this embodiment and the like, the memory cell 11 in the i-th row and the j-th column is sometimes denoted as a memory cell 11[i,j].

In the memory cell array 10, a plurality of wirings for writing and reading data in the memory cell 11 are arranged. FIG. 1A illustrates wirings WWL_1 to WWL_m, wirings WBL_1 to WBL_n, wirings RWL_1 to RWL_m, wirings RBL_1 to RBL_n, and wirings BGR_1 to BGR_m.

Note that a first wiring WWL (provided in the first row) is denoted as the wiring WWL_1, and an m-th wiring WWL (provided in the m-th row) is denoted as the wiring WWL_m. Note that in the case where a matter related to one memory cell 11 is described in this embodiment and the like, reference numerals representing ordinal numbers in the wirings are omitted in some cases. For example, the wirings WWL_1 to WWL_m are referred to as the wiring WWL in some cases.

The wirings WWL_1 to WWL_m (the wirings WWL) extend in the row direction. The wiring WWL is also referred to as a write word line. The wiring WWL supplies a write word signal to the memory cell 11. The write word signal is a signal that controls the timing of data writing to the memory cell 11.

The wirings WBL_1 to WBL_n (the wirings WBL) extend in the column direction. The wiring WBL is also referred to as a write bit line. The wiring WBL supplies a potential corresponding to a data signal (data) to the memory cell 11. The data signal is a signal written to the memory cell 11 and represented by two values which are a high-level (also referred to as “1” or V_{H}) and a low-level (also referred to as “0” or V_{L}).

The wirings RWL_1 to RWL_m (the wirings RWL) extend in the row direction. The wiring RWL is also referred to as a read word line. The wiring RWL supplies a read word signal to the memory cell 11. The read word signal is a signal that controls the timing of data reading from the memory cell 11.

The wirings RBL_1 to RBL_n (the wirings RBL) extend in the column direction. The wiring RBL is also referred to as a read bit line. The wiring RBL is a wiring for reading the potential corresponding to the data signal (data) retained in the memory cell 11. The data signal written to the memory cell 11 is precharged to the wiring RBL, and is read out to the outside by the potential of the wiring RBL that changes in accordance with the amount of current flowing in accordance with the data (“1” or “0”) written to the memory cell 11.

The wirings BGR_1 to BGR_m (the wirings BGR) extend in the row direction. The wiring BGR is also referred to as a control signal line. The wiring BGR supplies a signal (control signal) controlling the threshold voltage of the transistor included in the memory cell 11. The signal that controls the threshold voltage of the transistor is a signal represented by two values which are a high-level value (also referred to as V_{BGRH}) and a low-level value (also referred to as V_{BGRL}). When the signal that controls the threshold voltage of the transistor is at a high level (V_{BGRH}), the threshold voltage of the transistor shifts negatively and a current corresponding to the potential of the gate flows. Specifically, when the potential of the gate is the potential V_{H}, which is written to the memory cell 11, a current flows in accordance with the potential of the source. When the potential of the gate is the potential V_{L}, which is written to the memory cell 11, the potential of the gate is equal to the potential of the source and a current hardly flows. When the signal that controls the threshold voltage of the transistor is at a low level (V_{BGRL}), the threshold voltage of the transistor shifts positively and a current hardly flows regardless of the potential of the gate.

FIG. 1B illustrates a circuit structure applicable to the memory cell 11. The memory cell 11 illustrated in FIG. 1B includes transistors M1 and M2 and a capacitor C1. The transistor M1 includes a gate (also referred to as a “gate electrode”, a “front gate”, or a “first gate”). The transistor M2 includes a gate and a back gate (also referred to as a “back gate electrode” or a “second gate”). The gate and the back gate have regions overlapping with each other with a semiconductor layer therebetween. The back gate can control the threshold voltage of the transistor M2 by a signal that controls the threshold voltage of the transistor M2.

The transistor M1 is a write transistor in the memory cell 11. The gate of the transistor M1 is connected to the wiring WWL. One of a source and a drain of the transistor M1 is electrically connected to the wiring WBL. The other of the source and the drain of the transistor M1 is connected to one electrode of the capacitor C1 and the gate of the transistor M2. The other electrode of the capacitor C1 is connected to a wiring that supplies a fixed potential, such as a GND wiring. The capacitor C1 can be omitted when parasitic capacitance such as gate capacitance of the transistor M2 is used. Note that a wiring to which the other of the source and the drain of the transistor M1, the gate of the transistor M2, and the one electrode of the capacitor C1 are connected is referred to as a node FN (a node) in some cases.

The transistor M2 is a read transistor in the memory cell 11. The back gate of the transistor M2 is connected to the wiring BGR. One of a source and a drain of the transistor M2 is electrically connected to the wiring RWL. The other of the source and the drain of the transistor M2 is electrically connected to the wiring RBL.

Note that the description is made on the assumption that the transistors M1 and M2 described in this embodiment are both n-channel transistors. That is, the transistors M1 and M2 are brought into a conduction state (on state) when the gate is supplied with a high-level signal, and are brought into a non-conduction state (off state) when the gate is supplied with a low-level signal.

A circuit structure of the memory cell 11 illustrated in FIG. 1B is for a memory cell of a NOSRAM, which is a kind of a memory cell including an OS transistor. A NOSRAM (registered trademark) is an abbreviation for “Nonvolatile Oxide Semiconductor Random Access Memory (RAM)”. Note that the NOSRAM is referred to as a gain-cell type DRAM in some cases. In this case, the transistor M1 that is an access transistor needs to be an OS transistor, and the transistor M2 may be a transistor including a back gate, e.g., a Si transistor including a back gate.

Note that the transistors included in the memory cells 11 are preferably all OS transistors. That is, the transistors M1 and M2 are preferably OS transistors. In an OS transistor, a current that flows between the source and the drain in an off state, that is, an off-state current is extremely low. The NOSRAM can be used as a nonvolatile memory by retaining electric charge corresponding to data in the memory cell 11 with the use of the characteristic of an extremely low off-state current. In particular, the NOSRAM is capable of reading retained data without destruction (non-destructive reading), and thus is suitable for arithmetic processing in which only data reading operation is repeated many times.

When the memory cells 11 are arranged by stacking OS transistors, element layers including the memory cell arrays 10 can be stacked. In this case, a wiring that connects the memory cells and a peripheral circuit is provided in the direction perpendicular to the surface of the substrate, whereby the memory density of the memory cells 11 can be increased. The element layers including the memory cell arrays 10 can be manufactured in the perpendicular direction by repeating the same manufacturing process; thus, the manufacturing cost can be reduced.

Note that examples of a metal oxide employed for the OS transistor include indium oxide, gallium oxide, and zinc oxide. The metal oxide preferably includes two or three kinds selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

It is particularly preferable to use an oxide including indium (In), gallium (Ga), and zinc (Zn) (also referred to as IGZO) for the metal oxide. Alternatively, it is preferable to use an oxide including indium, tin, and zinc (also referred to as ITZO (registered trademark)). Further alternatively, it is preferable to use an oxide including indium, gallium, tin, and zinc. Further alternatively, it is preferable to use an oxide including indium (In), aluminum (Al), and zinc (Zn) (also referred to as IAZO). Further alternatively, it is preferable to use an oxide including indium (In), aluminum (Al), gallium (Ga), and zinc (Zn) (also referred to as IAGZO). Further alternatively, it is preferable to use an oxide including indium (In), gallium (Ga), zinc (Zn), and tin (Sn) (also referred to as IGZTO).

The metal oxide used in the OS transistors may include two or more metal oxide layers with different compositions. For example, a stacked-layer structure of a first metal oxide layer having In:M:Zn=1:3:4 [atomic ratio] or a composition in the neighborhood thereof and a second metal oxide layer that is provided over the first metal oxide layer and has In: M:Zn=1:1:1 [atomic ratio] or a composition in the neighborhood thereof can be suitably used.

Alternatively, a stacked structure of one selected from indium oxide, indium gallium oxide, and IGZO, and one selected from IAZO, IAGZO, and ITZO may be employed, for example.

The metal oxide used in the OS transistors preferably has crystallinity. Examples of an oxide semiconductor having crystallinity include a CAAC (c-axis aligned crystalline)-OS and an nc (nanocrystalline)-OS. When the oxide semiconductor having crystallinity is used, the semiconductor device can have high reliability.

In addition, the OS transistor operates stably even in a high-temperature environment and has a small variation in characteristics. For example, the off-state current hardly increases even in a high-temperature environment. Specifically, the off-state current hardly increases even at an environment temperature higher than or equal to room temperature and lower than or equal to 200° C. In addition, the on-state current is less likely to decrease even in a high-temperature environment. Thus, a memory cell including the OS transistor operates stably and has high reliability even in a high-temperature environment.

FIG. 1C is a timing chart for describing an operation example of the memory cell 11. FIG. 1C illustrates signals supplied to the wiring WWL, the wiring WBL, the wiring RWL, the wiring RBL, and the wiring BGR. Note that for the wiring RWL and the wiring BGR, wirings in a row where reading operation is performed are shown as RWL (selected) and BGR (selected), and wirings in a row where reading operation is not performed are shown as RWL (non-selected) and BGR (non-selected). FIG. 1C shows Periods T1 to T6. Period T1 is a stand-by period. T2 is a write period. Period T3 is a stand-by period. Periods T4 to T5 are read periods. T6 is a stand-by period. Note that FIG. 1C illustrates the data “1” or “0” written to the memory cell 11 through the wiring WBL. Regarding the data written to the memory cell 11, the data “1” is shown as high-level data and the data “0” is shown as low-level data.

FIG. 1C illustrates the data “1” or “0” read from the memory cell 11 through the wiring RBL. The wiring RBL is precharged to a high-level potential (VDD) in the read period, and data is read to an external read circuit connected to the wiring RBL in accordance with a change in the precharged potential. When the data retained in the memory cell 11 is the data “1”, a large amount of current flows through the transistor M2, whereby the potential of the wiring RBL is lowered. When the data retained in the memory cell is the data “0”, a small amount of current flows through the transistor M2, whereby a variation in the potential of the wiring RBL is small. That is, when the data retained in the memory cell 11 is the data “1”, the potential of the wiring RBL turns to a low level. When the data retained in the memory cell 11 is the data “0”, the potential of the wiring RBL turns to a high level (the precharged potential).

In Period T1, the wiring WWL is at a low level, the wiring WBL is at a low level (V_{L}), the wiring RWL (selected) is at a high level, the wiring RWL (non-selected) is at a high level, the wiring RBL is at a high level, the wiring BGR (selected) is at a high level (V_{BGRH}), and the wiring BGR (non-selected) is at a high level (V_{BGRH}). The transistor M1 is brought into a non-conduction state. A current does not flow through the transistor M2 since the potentials of the terminals serving as the source and the drain are equal to each other. Note that the potential of the gate of the transistor M2 is the potential V_{H} or V_{L} written in the previous write period.

In Period T2, the wiring WWL is at a high level, the wiring WBL has a signal (V_{H} or V_{L}) corresponding to data, the wiring RWL (selected) is at a high level, the wiring RWL (non-selected) is at a high level, the wiring RBL is at a high level, the wiring BGR (selected) is at a high level (V_{BGRH}), and the wiring BGR (non-selected) is at a high level (V_{BGRH}). The transistor M1 is brought into a conduction state, and the potential of the gate of the transistor M2 (the node FN) becomes a potential corresponding to the data. A current does not flow through the transistor M2 regardless of the potential of the gate since the potentials of the terminals serving as the source and the drain are equal to each other.

In Period T3, the wiring WWL is at a low level (V_{L}), the wiring WBL is at a low level (V_{L}), the wiring RWL (selected) is at a high level, the wiring RWL (non-selected) is at a high level, the wiring RBL is at a high level, the wiring BGR (selected) is at a high level (V_{BGRH}), and the wiring BGR (non-selected) is at a high level (V_{BGRH}). The transistors M1 and M2 are brought into a non-conduction state. In Period T2, the potential written to the potential of the gate of the transistor M2 (the node FN) is retained. A current does not flow through the transistor M2 regardless of the potential of the gate since the potentials of the terminals serving as the source and the drain are equal to each other.

In Period T4, the wiring WWL is at a low level, the wiring WBL is at a low level (V_{L}), the wiring RWL (selected) is at a high level, the wiring RWL (non-selected) is at a high level, the wiring BGR (selected) is at a high level (V_{BGRH}), and the wiring BGR (non-selected) is at a high level (V_{BGRH}). The wiring RBL is precharged to the high level (also referred to as a precharge voltage V_{PRE}). The transistor M1 is in a non-conduction state. The precharged voltage V_{PRE} is, for example, VDD and is equal to the high level of the wiring RBL. A current does not flow through the transistor M2 regardless of the potential of the gate since the potentials of the terminals serving as the source and the drain are equal to each other.

In Period T5, the wiring WWL is at a low level, the wiring WBL is at a low level (V_{L}), the wiring RWL (selected) is at a low level, the wiring RWL (non-selected) is at a high level, the wiring BGR (selected) is at a high level (V_{BGRH}), and the wiring BGR (non-selected) is at a low level (V_{BGRL}). The transistor M1 is brought into a non-conduction state. In Period T5, the wiring RBL is brought into an electrically floating state. That is, the potential varies in accordance with the current flowing through the transistor M2 in the memory cell 11.

In Period T5, in the memory cell 11 in the selected row, a signal that controls the threshold voltage of the transistor is at a high level (V_{BGRH}). Thus, the threshold voltage of the transistor is negatively shifted, and a current corresponding to the potential of the gate flows. In Period T5, a potential difference occurs between the terminals serving as the source and the drain of the transistor M2, whereby a current flows through the transistor M2 in accordance with the potential of the gate (the node FN). When the data retained in the memory cell 11 is the data “1”, a large amount of current flows through the transistor M2, whereby the potential of the wiring RBL is lowered to a low level. This change in the potential of the wiring RBL enables data in the selected memory cell 11 to be read out to the outside by activation of the sense amplifier connected to the wiring RBL. When the data retained in the memory cell 11 is the data “0”, a small amount of current flows through the transistor M2, whereby the potential of the wiring RBL remains at a high level (the precharged potential).

In Period T5, in the memory cell 11 in the non-selected row, a current does not flow through the transistor M2 regardless of the potential of the gate since the potentials of the terminals serving as the source and the drain are equal to each other in the initial state. In Period T5, in the memory cell 11 in the selected row, a current flows through the transistor M2, whereby the potential of the wiring RBL is lowered. Thus, the state where the potentials of the terminals serving as the source and the drain of the transistor M2 are equal to each other is changed, and a potential difference occurs between the high-level potential of the wiring RWL (non-selected) and the potential of the wiring RBL.

In the structure of one embodiment of the present invention, in Period T5, a signal that controls the threshold voltage of the transistor M2 in the memory cell 11 in the non-selected row is set to a low level (V_{BGRL}). Thus, the threshold voltage of the transistor is positively shifted, and a current hardly flows regardless of the potential of the gate. Accordingly, the above-described memory cell 11 in the selected row can have a structure in which even when the potential of the wiring RBL is lowered due to the current flowing through the transistor M2, a current hardly flows from the wiring RWL toward the wiring RBL. Thus, an increase in the potential of the wiring RBL due to the current from the wiring RWL through the transistor M2 in the memory cell 11 in the non-selected row can be inhibited. As a result, a semiconductor device that has excellent reliability of data to be read and is excellent in reducing power consumption can be obtained.

In Period T6, the wiring WWL is at a low level, the wiring WBL is at a low level (V_{L}), the wiring RWL (selected) is at a high level, the wiring RWL (non-selected) is at a high level, the wiring RBL is at a high level, the wiring BGR (selected) is at a high level (V_{BGRH}), and the wiring BGR (non-selected) is at a high level (V_{BGRH}). The transistor M1 is brought into a non-conduction state. A current does not flow through the transistor M2 regardless of the potential of the gate since the potentials of the terminals serving as the source and the drain are equal to each other.

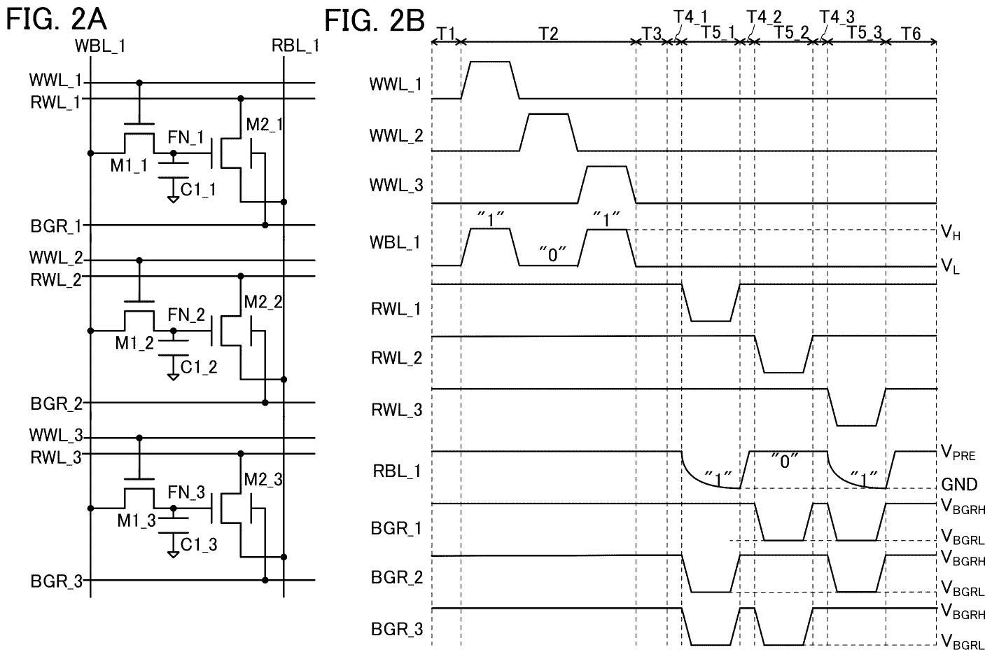

A more specific example of the structure illustrated in FIG. 1A to FIG. 1C is described. FIG. 2A is a structure example of a memory cell array in which the memory cells 11 described in FIG. 1B are provided in three rows and one column. FIG. 2A illustrates transistors M1_1 to M1_3 and M2_1 to M2_3 and capacitors C1_1 to C1_3. FIG. 2A also illustrates the wirings WWL_1 to WWL_3, the wiring WBL_1, the wirings RWL_1 to RWL_3, the wiring RBL_1, and the wirings BGR 1 to BGR 3.

FIG. 2B is a timing chart for describing an operation example of a memory cell array having three rows and one column illustrated in FIG. 2A. FIG. 2B illustrates signals supplied to the wirings WWL_1 to WWL_3, the wiring WBL_1, the wirings RWL_1 to RWL_3, the wiring RBL_1, and the wirings BGR_1 to BGR_3. Note that, “1”, “0”, and “1” are shown as data sequentially written to the memory cells provided in three rows and one column in the memory cell array. That is, a high level (V_{H}) is retained at a gate of the transistor M2_1 (a node FN_1) and a gate of the transistor M2_3 (a node FN_3), and a low level (V_{L}) is retained at a gate of the transistor M2_2 (a node FN_2).

FIG. 2B illustrates Periods T1 to T6. Periods T1 to T2 are write periods. Period T3 is a stand-by period. In Periods T1 to T2, the wirings WWL_1 to WWL_3 turn to high levels in this order, and a potential corresponding to the data of the wiring WBL is written to the memory cell. The above description also applies to Period T6.

Periods T4_1 to T4_3, Periods T5_1 to T5_3, and Period T6 illustrated in FIG. 2B correspond to Periods T4 to T6 described in FIG. 1C. Period T4_1 and Period T5_1 are periods for reading data from the memory cell in the first row and the first column. Period T4_2 and Period T5_2 are periods for reading data from the memory cell in the second row and the first column. Period T4_3 and Period T5_3 are periods for reading data from the memory cell in the third row and the first column.

In Period T4_1, the wirings WWL_1 to WWL_3 are at a low level, the wiring WBL_1 is at a low level (V_{L}), the wirings RWL_1 to RWL_3 are at a high level, and the wirings BGR_1 to BGR_3 are at a high level (V_{BGRH}). The wiring RBL_1 is precharged to a high level (also referred to as the precharge voltage V_{PRE}) and is brought into an electrically floating state. That is, the potential changes in accordance with the current flowing through the transistors M2_1 to M2_3. The transistors M1_2 to M1_3 are brought into a non-conduction state. The precharge voltage V_{PRE} is, for example, VDD, and is equal to the high level of the wiring RBL_1. A current does not flow through the transistors M2_1 to M2_3 regardless of the potential of the gate since the potentials of the terminals serving as the source and the drain are equal to each other.

In Period T5_1, the wirings WWL_1 to WWL_3 are at a low level, the wiring WBL_1 is at a low level (V_{L}), the wiring RWL_1 is at a low level, the wirings RWL_2 and RWL_3 (non-selected) are at a high level, the wiring BGR_1 is at a high level (V_{BGRH}), and the wirings BGR_2 and BGR_3 are at a low level (V_{BGRL}). The transistors M1_1 to M1_3 are brought into a non-conduction state.

In Period T5_1, in the transistor M2_1 in the first row, which is a selected row, a signal that controls the threshold voltage of the transistor is at a high level (V_{BGRH}). Thus, the threshold voltage of the transistor is negatively shifted, and a current corresponding to the potential of the gate flows. In Period T5_1, a potential difference occurs between the terminals serving as the source and the drain of the transistor M2_1, whereby a current flows through the transistor M2_1 in accordance with the potential of the gate (the node FN_1). Since the data retained at the node FN_1 is the data “1” (V_{H}), the gate source voltage (Vgs) is high. Thus, the current flowing through the transistor M2_1 increases, and the potential of the wiring RBL_1 is lowered to a low level.

In Period T5_1, in the transistor M2_2 in the second row, which is a non-selected row, a signal that controls the threshold voltage of the transistor is at a high level (V_{BGRL}). Thus, the threshold voltage of the transistor is positively shifted, and a current is less likely to flow even when the gate source voltage (Vgs) is high. In Period T5_1, in the transistor M2_2 in the second row, which is a non-selected row, a current does not flow through the transistor M2_2 regardless of the potential of the gate since the potentials of the terminals serving as the source and the drain are equal to each other in the initial state. In Period T5_1, a current flows through the transistor M2_1 in the selected row, whereby the potential of the wiring RBL_1 is lowered. Thus, the state where the potentials of the terminals serving as the source and the drain of the transistor M2_2 are equal to each other is changed, and a potential difference occurs between the high-level potential of the wiring RWL_2 and the potential of the wiring RBL_1. Since the data retained at the potential of the gate of the transistor M2_2 (the node FN_2) is the data “0” (V_{L}), the gate-source voltage (Vgs) is low. Thus, the current flowing through the transistor M2_2 is small.

In Period T5_1, in the transistor M2_2 in the third row, which is a non-selected row, a signal that controls the threshold voltage of the transistor is at a high level (V_{BGRL}). Thus, the threshold voltage of the transistor is positively shifted, and a current is less likely to flow even when the gate-source voltage (Vgs) is high. In Period T5_1, in the transistor M2_3 in the third row, which is a non-selected row, a current does not flow through the transistor M2_3 regardless of the potential of the gate since the potentials of the terminals serving as the source and the drain are equal to each other in the initial state. In Period T5_1, a current flows through the transistor M2_1 in the selected row, whereby the potential of the wiring RBL_1 is lowered. Thus, the state where the potentials of the terminals serving as the source and the drain of the transistor M2_3 are equal to each other is changed, and a potential difference occurs between the high-level potential of the wiring RWL_3 and the potential of the wiring RBL_1. Since the data retained at the potential of the gate of the transistor M2_3 (the node FN_3) is the data “1” (V_{H}), the gate-source voltage (Vgs) is increased; meanwhile, the current flowing through the transistor M2_3 is less likely to flow due to the above-described positive shift of the threshold voltage of the transistor.

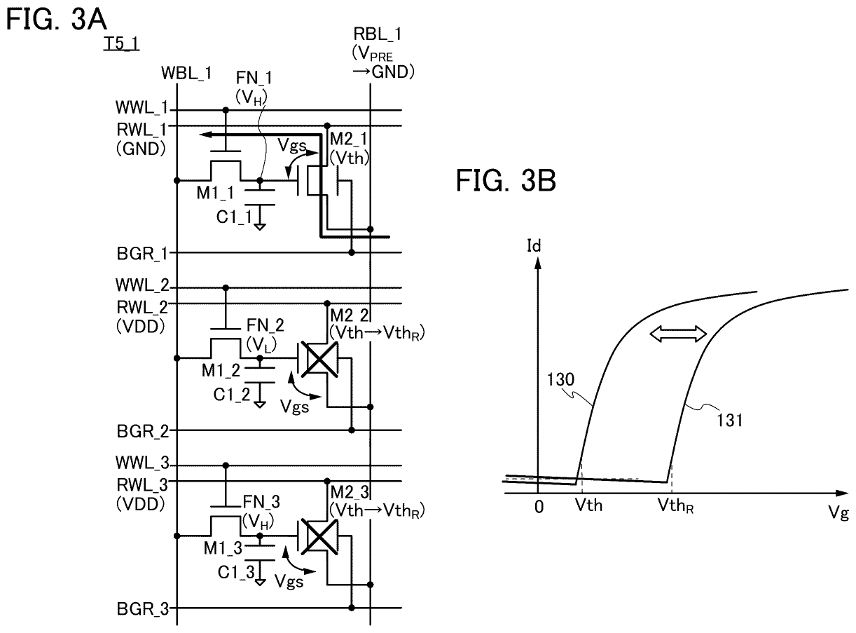

FIG. 3A schematically illustrates the above-described reading operation of data from the memory cells in three rows and one column in Period T5_1 described above. FIG. 3B shows electrical characteristics (Id-Vg electrical characteristics) of a transistor that are changed by a signal that controls the threshold voltage of the transistor. In FIG. 3B, a graph 130 is a curve when V_{BGRH} is applied to the back gate, and shows a threshold voltage Vth. In FIG. 3B, a graph 131 is a curve when V_{BGRL} is applied to the back gate, and shows a threshold voltage Vth_{R} (>Vth). Note that the Id-Vg electrical characteristics shown in FIG. 3B are the Id-Vg electrical characteristics of an n-channel transistor. The Id-Vg electrical characteristics represent a change in drain current (Id) with respect to a change in gate voltage (Vg).

In FIG. 3A, in the transistor M2_1 in the first row, which is a selected row, a current corresponding to the potential of the node FN_1 flows when the threshold voltage is reduced like Vth illustrated in FIG. 3B. A current flows through a path indicated by a solid arrow. Since the node FN_1 has the data “1” (V_{H}), the transistor M2_1 is brought into a conduction state.

In FIG. 3A, the threshold voltages of the transistors M2_2 and M2_3 in the second and third rows, which are non-selected rows, are increased like Vth_{R} illustrated in FIG. 3B. Thus, a current flowing can be reduced regardless of the potentials of the nodes FN_2 and FN_3. The transistors M2_2 and M2_3 are brought into a non-conduction state (expressed by crosses in the diagram).

Period T4-2 is similar to Period T4-1. In Period T5_2, since the node FN_2 has the data “0” (V_{L}), the transistor M2_2 in the second row, which is a selected row, is brought into a non-conduction state. Thus, unlike in Period T5-1, a decrease in the potential of the wiring RBL due to the reading operation does not occur. Period T4-3 is similar to Period T4-1. In Period T5_3, since the node FN_3 has the data “1” (V_{H}), the transistor M2_3 in the third row, which is a selected row, is brought into a conduction state. Thus, although a decrease in the potential of the wiring RBL occurs as in Period T5-1, the threshold voltages of the transistors M2_1 and M2_2 are high like Vth_{R} illustrated in FIG. 3B, whereby currents flowing through the transistors can be reduced regardless of the potentials of the nodes FN_1 and FN_2.

In the structure of one embodiment of the present invention, in Period T5-1 or T5-3, a signal that controls the threshold voltage of the transistor M2_1 or M2_3 in the memory cell 11 in the non-selected row is set to a low level (V_{BGRL}). Thus, the threshold voltage of the transistor is positively shifted, and a current hardly flows regardless of the potential of the gate. Accordingly, it is possible to obtain a structure in which even when the potential of the wiring RBL_1 is lowered due to the current flowing through the above-described transistor M2_1 or M2_3 in the selected row, a current hardly flows from the wiring RWL_1 or RWL_3 toward the wiring RBL_1. Thus, an increase in the potential of the wiring RBL_1 due to the current from the wiring RWL_2 or RWL_3 through the transistor M2_1 or M2_3 in the non-selected row can be inhibited. As a result, a semiconductor device that has excellent reliability of data to be read and is excellent in reducing power consumption can be obtained.

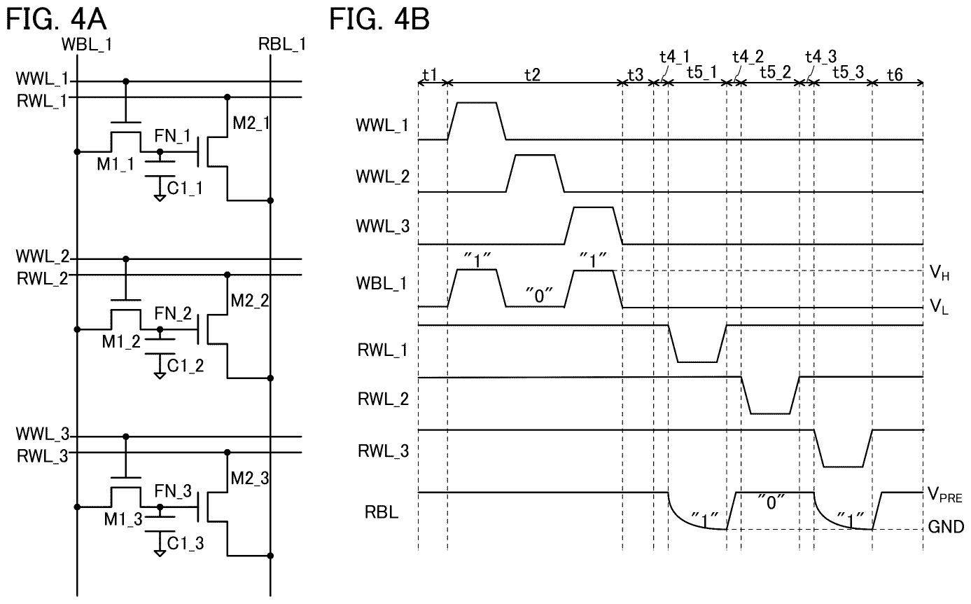

Here, FIG. 4A illustrates a structure for comparing with the structure of one embodiment of the present invention. FIG. 4A illustrates a structure example of a memory cell array having three rows and one column in which the transistors M2_1 to M2_3 do not have back gates connected to the wirings BGR_1 to BGR_3 in the structure illustrated in FIG. 2A. FIG. 4B is an ideal timing chart for illustrating an operation example of the memory cell array having three rows and one column illustrated in FIG. 4A.

FIG. 4B illustrates an operation example without the wirings BGR_1 to BGR_3 in the timing chart illustrated in FIG. 2B. The operations in Periods t1 to t6 illustrated in FIG. 4B are similar to those in Periods T1 to T6 in FIG. 2B except that the wirings BGR_1 to BGR_3 are not provided.

In the case of FIG. 4B, in Period t5_1, the wirings WWL_1 to WWL_3 are at a low level, the wiring WBL_1 is at a low level (V_{L}), the wiring RWL_1 is at a low level, and the wirings RWL_2 and RWL_3 (non-selected) are at a high level.

In Period t5_1 in FIG. 4B, in the transistor M2_3 in the third row, which is a non-selected row, a current does not flow through the transistor M2_3 regardless of the potential of the gate since the potentials of the terminals serving as the source and the drain are equal to each other (V_{PRE}=VDD) in the initial state. In Period T5_1, a current flows through the transistor M2_1 in the selected row, whereby the potential of the wiring RBL_1 is lowered toward a GND potential. Thus, the state where the potentials of the terminals serving as the source and the drain of the transistor M2_3 are equal to each other is changed, and a potential difference occurs between the high-level potential of the wiring RWL_3 and the potential of the wiring RBL_1. Since the data retained at the potential of the gate of the transistor M2_3 (the node FN_3) is the data “1” (V_{H}), the gate-source voltage (Vgs) is increased. Thus, the amount of current flowing through the transistor M2_3 in the third row, which is a non-selected row, is increased. As a result, the potential of the wiring RBL_1 turns to a potential GND+V1 that is increased from the GND potential.

Similarly, in Period t5_3 in FIG. 4B, in the transistor M2_1 in the first row, which is a non-selected row, a current does not flow through the transistor M2_1 regardless of the potential of the gate since the potentials of the terminals serving as the source and the drain are equal to each other (V_{PRE}=VDD) in the initial state. In Period t5_3, a current flows through the transistor M2_3 in the selected row, whereby the potential of the wiring RBL_1 is lowered toward the GND potential. Thus, the state where the potentials of the terminals serving as the source and the drain of the transistor M2_1 equal are equal to each other is changed, and a potential difference occurs between the high-level potential of the wiring RWL_1 and the potential of the wiring RBL_1. Since the data retained at the potential of the gate of the transistor M2_1 (the node FN_1) is the data “1” (V_{H}), the gate-source voltage (Vgs) is increased. Thus, the amount of current flowing through the transistor M2_1 in the first row, which is a non-selected row, is increased. As a result, the potential of the wiring RBL_1 turns to the potential GND+V1, which is increased from the GND potential.

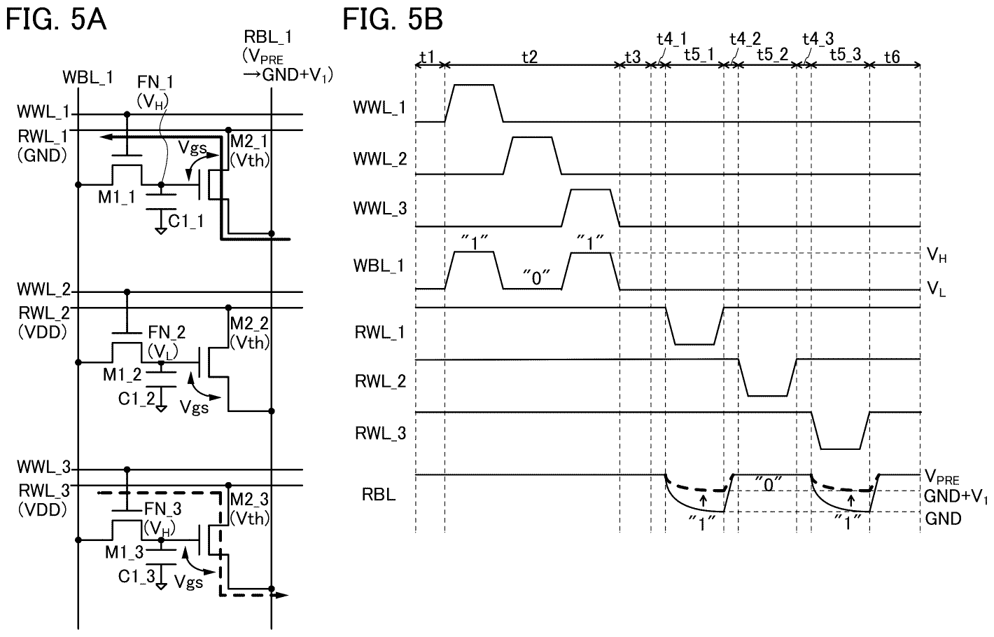

FIG. 5A schematically illustrates a current path of the wiring RBL_1 by the operation of reading data from the memory cells in three rows and one column in Period t5_1 in FIG. 4B. In FIG. 5A, the threshold voltages of the transistors M2_1 to M2_3 are denoted by Vth. Vth corresponds to Vth described in FIG. 3B. FIG. 5B is a diagram illustrating how the timing chart is influenced by currents flowing through the transistor M2_1 in the first row, which is a non-selected row, and the transistor M2_3 in the third row, which is a non-selected row, in Period t5_1 and Period t5_3 illustrated in FIG. 4A and FIG. 4B.

In FIG. 5A, in the transistor M2_1 in the first row, which is a selected row, a current corresponding to the potential of the node FN_1 flows. A current flows through a path indicated by a solid arrow. Since the node FN_1 has the data “1” (V_{H}), the transistor M2_1 is brought into a conduction state.

In FIG. 5A, in the transistor M2_2 in the second row, which is a non-selected row, a current does not flow through the transistor M2_2 regardless of the potential of the gate since the potentials of the terminals serving as the source and the drain are equal to each other (V_{PRE}=VDD) in the initial state. In Period t5_1 in FIG. 4B, a current flows through the transistor M2_1 in the selected row, whereby the potential of the wiring RBL_1 is lowered toward the GND potential. Thus, the state where the potentials of the terminals serving as the source and the drain of the transistor M2_3 are equal to each other is changed, and a potential difference occurs between the high-level potential of the wiring RWL_2 and the potential of the wiring RBL_1. Since the data retained at the potential of the gate of the transistor M2_2 (the node FN_2) is the data “0” (V_{L}), the gate-source voltage (Vgs) is low. Thus, the current flowing through the transistor M2_2 in the second row, which is a non-selected row, remains small.

Meanwhile, in FIG. 5A, in the transistor M2_3 in the third row, which is a non-selected row, a current does not flow through the transistor M2_3 regardless of the potential of the gate since the potentials of the terminals serving as the source and the drain are equal to each other (V_{PRE}=VDD) in the initial state. In Period t5_1 in FIG. 4B, a current flows through the transistor M2_1 in the selected row, whereby the potential of the wiring RBL_1 is lowered toward the GND potential. Thus, the state where the potentials of the terminals serving as the source and the drain of the transistor M2_3 are equal to each other is changed, and a potential difference occurs between the high-level potential of the wiring RWL_2 (non-selected) and the potential of the wiring RBL_1. Since the data retained at the potential of the gate of the transistor M2_3 (the node FN_3) is the data “1” (V_{H}), the gate-source voltage (Vgs) is high. Thus, the amount of current flowing through the transistor M2_3 in the third row, which is a non-selected row, is increased. A current flows through a path indicated by a dotted arrow. The potential of the wiring RBL_1 turns to the potential GND+V1, which is increased from the GND potential.

When a current flows in the above non-selected rows at the time of the reading operation, the potential of the wiring RBL_1 increases in Period t5_1 and Period t5_3 as illustrated in FIG. 4B. As a result, the reliability of data to be read might be decreased, and power consumption might be increased.

In the structure of one embodiment of the present invention, as described in FIG. 2A, FIG. 2B, FIG. 3A, and FIG. 3B, in Period T5_1 or T5_3, a signal that controls the threshold voltage of the transistor M2_1 or M2_3 in the memory cell 11 in the selected row is set to a low level (V_{BGRL}). Thus, the threshold voltage of the transistor is positively shifted, and a current hardly flows regardless of the potential of the gate. Accordingly, it is possible to obtain a structure in which even when the potential of the wiring RBL_1 is lowered due to the current flowing through the above-described transistor M2_1 or M2_3 in the selected row, a current hardly flows from the wiring RWL_1 or RWL_3 toward the wiring RBL_1. Thus, an increase in the potential of the wiring RBL_1 due to the current from the wiring RWL_2 or RWL_3 through the transistor M2_1 or M2_3 in the non-selected row can be inhibited. As a result, a semiconductor device that has excellent reliability of data to be read and is excellent in reducing power consumption can be obtained.

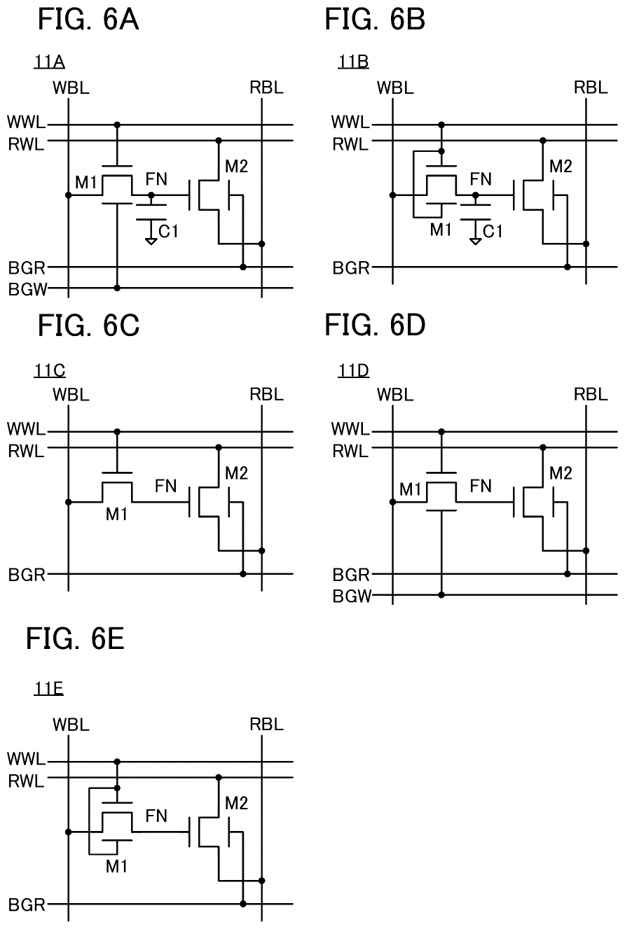

Variation examples of memory cells used as the memory cells 11 are described with reference to FIG. 6A to FIG. 6E.

FIG. 6A illustrates a structure example of a two-transistor (2T) NOSRAM cell applicable to the memory cell 11. In a memory cell 11A illustrated in FIG. 6A, the transistor M1 includes a back gate. The back gate of the transistor M1 is connected to a wiring BGW. The wiring BGW is supplied with a signal that controls the threshold voltage of the transistor M1. With this structure, the transistor M1 can be brought into a non-conduction state more surely. Accordingly, retaining electric charge corresponding to the potential of the data signal supplied to the node FN can be made easier.

FIG. 6B illustrates another example of a two-transistor (2T) NOSRAM cell applicable to the memory cell 11. In a memory cell 11B illustrated in FIG. 6B, the transistor M1 includes a back gate. The back gate of the transistor M1 is connected to the gate of the transistor M1. With this structure, the amount of current flowing through the transistor M1 at the time of bringing M1 into a conduction state can be increased and the amount of current flowing through the transistor M1 at the time of bringing M1 into a non-conduction state can be decreased.

FIG. 6C illustrates another example of a two-transistor (2T) NOSRAM cell applicable to the memory cell 11. A memory cell 11C illustrated in FIG. 6C has a structure in which the capacitor C1 is omitted in the memory cell 11 illustrated in FIG. 1B and the like. As the capacitance corresponding to the capacitor C1, the gate capacitance, the parasitic capacitance, or the like of the transistor M2 can be used.

FIG. 6D illustrates another example of a two-transistor (2T) NOSRAM cell applicable to the memory cell 11. A memory cell 11D illustrated in FIG. 6D has a structure in which the capacitor C1 is omitted in the memory cell 11A described in FIG. 6A. As the capacitance corresponding to the capacitor C1, the gate capacitance, the parasitic capacitance, or the like of the transistor M2 can be used.

FIG. 6E illustrates another example of a two-transistor (2T) NOSRAM cell applicable to the memory cell 11. A memory cell 11E illustrated in FIG. 6E has a structure in which the capacitor C1 is omitted in the memory cell 11B described in FIG. 6B. As the capacitance corresponding to the capacitor C1, the gate capacitance, the parasitic capacitance, or the like of the transistor M2 can be used.

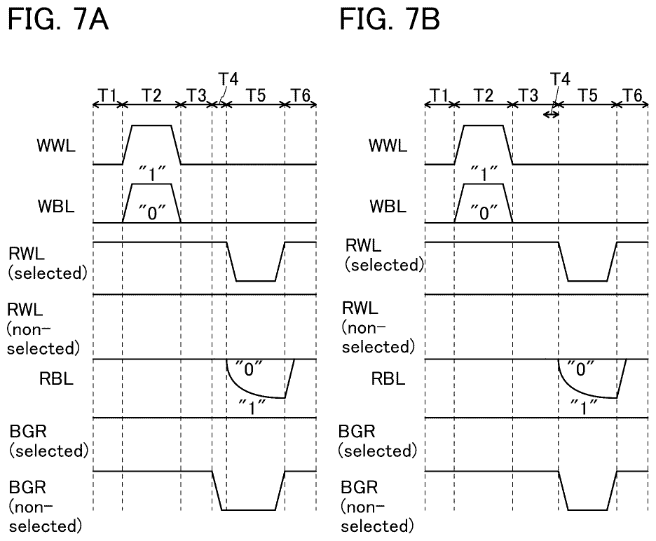

Variation examples of the timing chart applied to the operation example of the memory cell 11 are described with reference to FIG. 7A and FIG. 7B.

FIG. 7A illustrates a structure example in which BGR (non-selected) is set to a low level in Period T4 in the timing chart in FIG. 1C. By switching the signal that controls the threshold voltage of the transistor M2 in the period in which the wiring RBL is precharged, the operation in Period T5 can be performed at high speed.

FIG. 7B illustrates a structure example in which precharge operation is performed in Period T3, which is a standby period, in the timing chart in FIG. 1C. The structure example illustrated in FIG. 7B is a structure in which the operation corresponding to Period T4 is performed in Period T3. With this structure, the reading period can be shortened.

In the structure of one embodiment of the present invention, in Period T5, a signal that controls the threshold voltage of the transistor M2 in the memory cell 11 in the selected row is set to a low level (V_{BGRL}). Thus, the threshold voltage of the transistor is positively shifted, and a current hardly flows regardless of the potential of the gate. Accordingly, the above-described memory cell 11 in the selected row can have a structure in which even when the potential of the wiring RBL is lowered due to the current flowing through the transistor M2, a current hardly flows from the wiring RWL toward the wiring RBL. Thus, an increase in the potential of the wiring RBL due to the current from the wiring RWL through the transistor M2 in the memory cell 11 in the non-selected row can be inhibited. As a result, a semiconductor device that has excellent reliability of data to be read and is excellent in reducing power consumption can be obtained.

### Embodiment 2

In this embodiment, structure examples of a storage device in which a semiconductor device of one embodiment of the present invention and a method for driving the semiconductor device can be applied are described with reference to drawings.

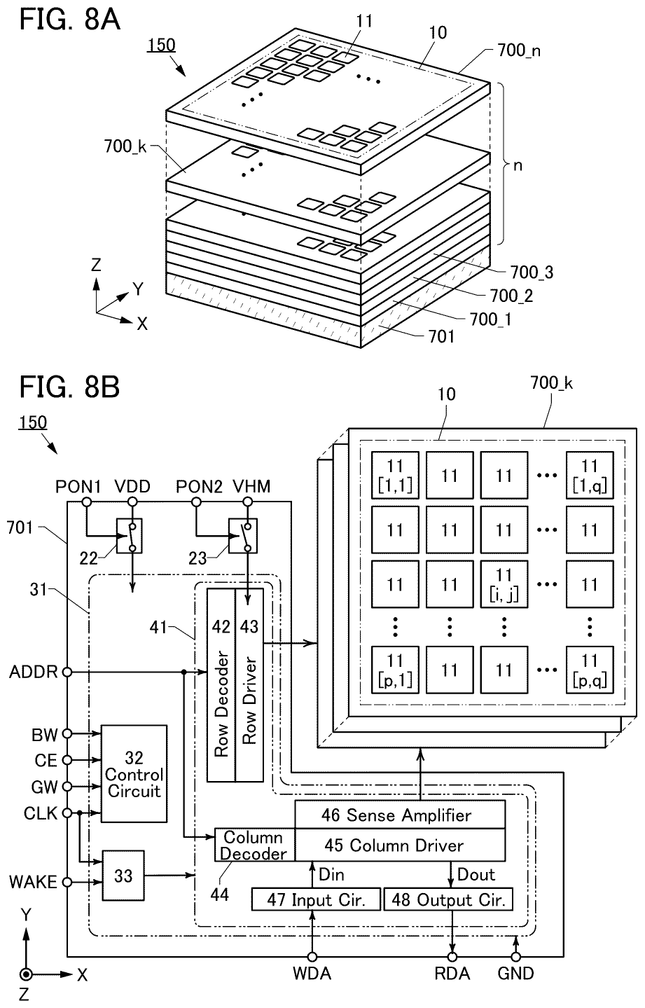

FIG. 8A is a schematic perspective view of a storage device of one embodiment of the present invention. FIG. 8B illustrates a block diagram of the storage device of one embodiment of the present invention.

A storage device 150 illustrated in FIG. 8A and FIG. 8B includes a driver circuit layer 701 and n memory layers 700. Each of the memory layers 700 includes the memory cell array 10. The memory cell array 10 includes a plurality of the memory cells 11.

The n memory layers 700 are provided over the driver circuit layer 701. Provision of the n memory layers 700 over the driver circuit layer 701 can reduce the area occupied by the storage device 150. Furthermore, storage capacity per unit area can be increased.

In this embodiment and the like, the first memory layer 700 is referred to as a memory layer 700_1, the second memory layer 700 is referred to as a memory layer 700_2, and the third memory layer 700 is referred to as a memory layer 700_3. Furthermore, the k-th (k is an integer greater than or equal to 1 and less than or equal to n.) memory layer 700 is referred to as a memory layer 700_k, and the n-th memory layer 700 is referred to as a memory layer 700_n. Note that in this embodiment and the like, the simple term “memory layer 700” is sometimes used in the case of describing matters related to all the n memory layers 700 or matters common to the n memory layers 700.

The driver circuit layer 701 includes a PSW 22 (power switch), a PSW 23, and a peripheral circuit 31. The peripheral circuit 31 includes a peripheral circuit 41, a control circuit 32, and a voltage generation circuit 33.

In the storage device 150, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 150. For example, the control circuit performs a logical operation on the signal CE, the signal GW, and the signal BW to determine an operation mode (e.g., a writing operation or a reading operation) of the storage device 150. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 11. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 11, a function of reading data from the memory cells 11, a function of retaining the read data, and the like. The column driver 45 has a function of selecting a wiring WBL (write bit line) or a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 11. Data (Dout) read from the memory cells 11 by the column driver 45 is output to the output circuit 48. The output circuit 48 has a function of retaining Dout. In addition, the output circuit 48 has a function of outputting Dout to the outside of the storage device 150. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 150, a high power supply voltage is VDD and a low power supply voltage is GND (a ground potential). In addition, VHM is a high power supply voltage used to set the word line at high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 8B but can be more than one. In such a case, a power switch is provided for each power domain.

A structure example of the n memory layers 700 will be described. Each of the n memory layers 700 includes the memory cell array 10. The memory cell array 10 includes the plurality of memory cells 11. FIG. 8A and FIG. 8B illustrate an example in which the memory cell array 10 includes the plurality of memory cells 11 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 8B, the memory cell 11 provided in the first row and the first column is referred to as a memory cell 11[1,1], and the memory cell 11 provided in the p-th row and the q-th column is referred to as a memory cell 11[p,q]. In addition, the memory cell 11 provided in the i-th row and the j-th column (i is an integer greater than or equal to 1 and less than or equal to p. j is an integer greater than or equal to q.) is indicated as a memory cell 11[i,j].

As a circuit structure example of the memory cells 11, the structure described in the above embodiment can be employed. With the use of the method for driving the semiconductor device of one embodiment of the present invention, the memory cell 11 can be a highly power saving and highly reliable semiconductor device.

In the case where the memory layers 700 are stacked, it is preferable to arrange the wiring WBL and the wiring RBL in a direction perpendicular to the substrate surface. When the wiring WBL and the wiring RBL are provided in the direction perpendicular to the surface of the substrate, the length of the wiring between the memory layer 700 and the driver circuit layer 701 can be shortened. Accordingly, a signal transmission distance from the sense amplifier connected to the wiring WBL and the wiring RBL can be shortened, and the resistance and parasitic capacitance of the wiring WBL and the wiring RBL can be significantly reduced; hence, power consumption and signal delays can be reduced.

The configuration, structure, method, and the like described in this embodiment can be used in combination as appropriate with the configurations, structures, methods, and the like described in the other embodiments, an example, and the like.

### Embodiment 3

In this embodiment, structures of transistors that can be used in the semiconductor device described in the above embodiment will be described. As an example, a structure in which transistors having different electrical characteristics are stacked will be described. With this structure, the degree of freedom in design of a semiconductor device can be increased. In addition, providing transistors having different electrical characteristics to be stacked can increase the integration degree of the semiconductor device.

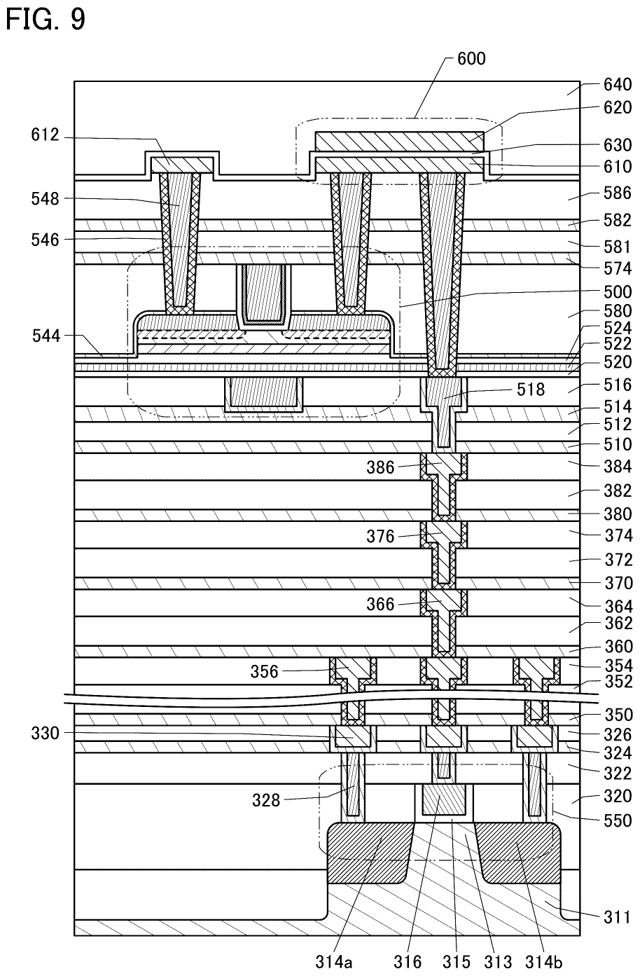

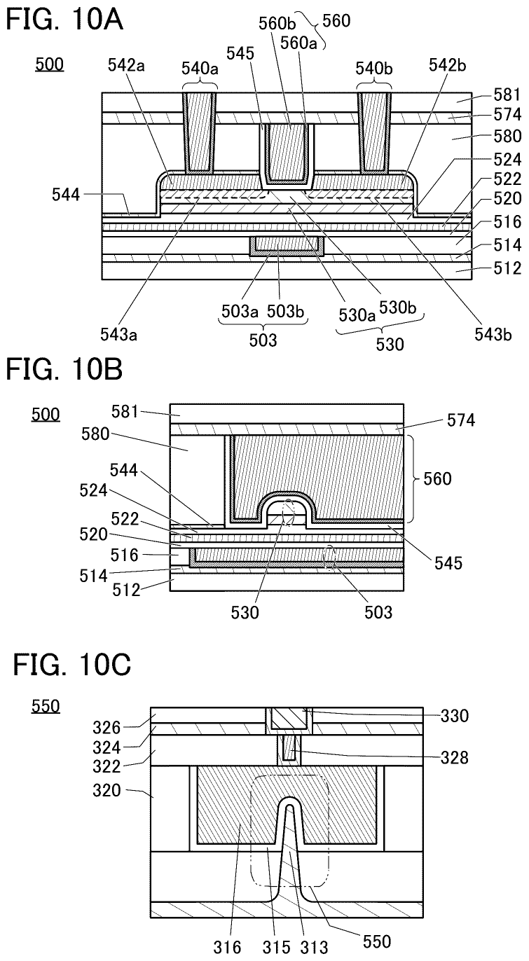

FIG. 9 illustrates part of a cross-sectional structure of a semiconductor device. The semiconductor device illustrated in FIG. 9 includes a transistor 550, a transistor 500, and a capacitor 600. FIG. 10A is a cross-sectional view of the transistor 500 in the channel length direction, FIG. 10B is a cross-sectional view of the transistor 500 in the channel width direction, and FIG. 10C is a cross-sectional view of the transistor 550 in the channel width direction. For example, the transistor 500 corresponds to the Si transistor described in the above embodiment, and the transistor 550 corresponds to an OS transistor.

In FIG. 9, the transistor 500 is provided above the transistor 550, and the capacitor 600 is provided above the transistor 550 and the transistor 500.

The transistor 550 is provided in a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 10C, the top surface and the side surface in the channel width direction of the semiconductor region 313 of the transistor 550 are covered with the conductor 316 with the insulator 315 positioned therebetween. Such a Fin-type transistor 550 can have an increased effective channel width and thus have improved on-state characteristics. In addition, contribution of the electric field of a gate electrode can be increased, so that the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably include a semiconductor such as a silicon-based semiconductor, and preferably include single crystal silicon. Alternatively, the regions may be formed using a material including Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 550 may be a HEMT (High Electron Mobility Transistor) using GaAs and GaAlAs, or the like.

The low-resistance region 314a and the low-resistance region 314b include an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, it is possible to use a semiconductor material such as silicon including the element that imparts n-type conductivity, such as arsenic or phosphorus, or the element that imparts p-type conductivity, such as boron, or a conductive material such as a metal material, an alloy material, or a metal oxide material.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (silicon on Insulator) substrate or the like.

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature annealing, and an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A transistor formed using a single crystal substrate includes a single crystal semiconductor in a channel formation region.

An insulator 320, an insulator 322, an insulator 324, and an insulator 326 are sequentially stacked and provided to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to have improved planarity.

For the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, silicon nitride deposited by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

A conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. A plurality of conductors functioning as plugs or wirings are collectively denoted by the same reference numeral in some cases. In this specification and the like, a wiring and a plug connected to the wiring may be a single component. That is, part of a conductor functions as a wiring in some cases and part of a conductor functions as a plug in other cases.

As a material for each of the plugs and wirings (the conductor 328, the conductor 330, and the like), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, an insulator 350, an insulator 352, and an insulator 354 are stacked sequentially in FIG. 9. Furthermore, a conductor 356 is formed in the insulator 350, the insulator 352, and the insulator 354. The conductor 356 has a function of a plug or a wiring that is connected to the transistor 550. Note that the conductor 356 can be formed using a material similar to that for the conductor 328 and the conductor 330.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. With this structure, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. By stacking tantalum nitride and tungsten, which has high conductivity, diffusion of hydrogen from the transistor 550 can be inhibited while the conductivity as a wiring is ensured. In that case, a tantalum nitride layer having a barrier property against hydrogen is preferably in contact with the insulator 350 having a barrier property against hydrogen.

A wiring layer may be provided over the insulator 354 and the conductor 356. For example, an insulator 360, an insulator 362, and an insulator 364 are stacked sequentially in FIG. 9. Furthermore, a conductor 366 is formed in the insulator 360, the insulator 362, and the insulator 364. The conductor 366 has a function of a plug or a wiring. Note that the conductor 366 can be formed using a material similar to that for the conductor 328 and the conductor 330.

Note that for example, the insulator 360 is preferably formed using an insulator having a barrier property against hydrogen, like the insulator 324. Furthermore, the conductor 366 preferably includes a conductor having a barrier property against hydrogen. The conductor having a barrier property against hydrogen is formed particularly in an opening portion of the insulator 360 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 364 and the conductor 366. For example, an insulator 370, an insulator 372, and an insulator 374 are stacked sequentially in FIG. 9. Furthermore, a conductor 376 is formed in the insulator 370, the insulator 372, and the insulator 374. The conductor 376 has a function of a plug or a wiring. Note that the conductor 376 can be formed using a material similar to that for the conductor 328 and the conductor 330.

Note that for example, the insulator 370 is preferably formed using an insulator having a barrier property against hydrogen, like the insulator 324. Furthermore, the conductor 376 preferably includes a conductor having a barrier property against hydrogen. The conductor having a barrier property against hydrogen is formed particularly in an opening portion of the insulator 370 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 374 and the conductor 376. For example, an insulator 380, an insulator 382, and an insulator 384 are stacked sequentially in FIG. 9. Furthermore, a conductor 386 is formed in the insulator 380, the insulator 382, and the insulator 384. The conductor 386 has a function of a plug or a wiring. Note that the conductor 386 can be formed using a material similar to that for the conductor 328 and the conductor 330.

Note that for example, the insulator 380 is preferably formed using an insulator having a barrier property against hydrogen, like the insulator 324. Furthermore, the conductor 386 preferably includes a conductor having a barrier property against hydrogen. The conductor having a barrier property against hydrogen is formed particularly in an opening portion of the insulator 380 having a barrier property against hydrogen. With this structure, the transistor 550 and the transistor 500 can be separated with a barrier layer, so that hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device according to this embodiment is not limited thereto. The number of wiring layers similar to the wiring layer including the conductor 356 may be three or less, or five or more.

An insulator 510, an insulator 512, an insulator 514, and an insulator 516 are sequentially stacked and provided over the insulator 384. A substance having a barrier property against oxygen, hydrogen, or the like is preferably used for any of the insulator 510, the insulator 512, the insulator 514, and the insulator 516.

For example, for each of the insulator 510 and the insulator 514, it is preferable to use a film having a barrier property that prevents diffusion of hydrogen, impurities, or the like from the substrate 311, a region where the transistor 550 is provided, or the like into a region where the transistor 500 is provided. Thus, a material similar to that for the insulator 324 can be used.

For the film having a barrier property against hydrogen, silicon nitride deposited by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

For the film having a barrier property against hydrogen used for each of the insulator 510 and the insulator 514, for example, a metal oxide such as aluminum oxide, hafnium oxide, or tantalum oxide is preferably used.

In particular, aluminum oxide has an excellent blocking effect that prevents passage of both oxygen and impurities such as hydrogen and moisture that cause a change in electrical characteristics of the transistor. Accordingly, the use of aluminum oxide can prevent entry of impurities such as hydrogen and moisture into the transistor 500 during and after a fabrication process of the transistor. In addition, release of oxygen from the oxide included in the transistor 500 can be inhibited. Thus, aluminum oxide is suitably used for a protective film of the transistor 500 The insulator 512 and the insulator 516 can be formed using a material similar to that for the insulator 320, for example. In the case where a material with relatively low permittivity is used for these insulators, the parasitic capacitance between wirings can be reduced. A silicon oxide film, a silicon oxynitride film, or the like can be used for the insulator 512 and the insulator 516, for example.

A conductor 518, a conductor included in the transistor 500 (e.g., a conductor 503), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be formed using a material similar to that for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated with a layer having a barrier property against oxygen, hydrogen, and water, so that hydrogen diffusion from the transistor 550 into the transistor 500 can be inhibited.

The transistor 500 is provided above the insulator 514.

As illustrated in FIG. 10A and FIG. 10B, the transistor 500 includes the conductor 503 placed so as to be embedded in the insulator 514 and the insulator 516, an insulator 520 placed over the insulator 516 and the conductor 503, an insulator 522 placed over the insulator 520, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and has an opening overlapping with an area between the conductor 542a and the conductor 542b, an insulator 545 placed on the bottom surface and a side surface of the opening, and a conductor 560 that is placed on the formation surface of the insulator 545.

As illustrated in FIG. 10A and FIG. 10B, an insulator 544 is preferably placed between the insulator 580 and the oxide 530a, the oxide 530b, the conductor 542a, and the conductor 542b. In addition, as illustrated in FIG. 10A and FIG. 10B, the conductor 560 preferably includes a conductor 560a provided inside the insulator 545 and a conductor 560b provided to be embedded inside the conductor 560a. Moreover, as illustrated in FIG. 10A and FIG. 10B, an insulator 574 is preferably placed over the insulator 580, the conductor 560, and the insulator 545.

Note that in this specification and the like, the oxide 530a and the oxide 530b may be collectively referred to as an oxide 530.

Note that the transistor 500 is illustrated to have a structure in which two layers, the oxide 530a and the oxide 530b, are stacked in the region where the channel is formed and its vicinity; however, the present invention is not limited thereto. For example, a single layer of the oxide 530b or a stacked-layer structure of three or more layers may be provided.

Although the conductor 560 has a two-layer structure in the transistor 500, the present invention is not limited thereto. For example, the conductor 560 may have a single-layer structure or a stacked-layer structure of three or more layers. The transistor 500 illustrated in FIG. 9 and FIG. 10A is just an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Therefore, the conductor 560 can be formed without an alignment margin, resulting in a reduction in the area occupied by the transistor 500. Accordingly, miniaturization and high integration of the semiconductor device can be achieved.

Since the conductor 560 is formed in the region between the conductor 542a and the conductor 542b in a self-aligned manner, the conductor 560 does not have a region overlapping with the conductor 542a or the conductor 542b. Thus, parasitic capacitance between the conductor 560 and each of the conductor 542a and the conductor 542b can be reduced. As a result, the transistor 500 can have increased switching speed and excellent frequency characteristics.

The conductor 560 sometimes functions as a first gate (also referred to as top gate) electrode. The conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, a drain current at the time when a potential applied to the conductor 560 is 0 V can be made lower in the case where a negative potential is applied to the conductor 503 than in the case where a negative potential is not applied to the conductor 503.

The conductor 503 is positioned to overlap with the oxide 530 and the conductor 560. Accordingly, when a potential is applied to the conductor 560 and the conductor 503, an electric field generated from the conductor 560 and an electric field generated from the conductor 503 are connected, thereby covering the channel formation region in the oxide 530.

In this specification and the like, a transistor structure where a channel formation region is electrically surrounded by an electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor has the S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. In the transistor having any of the S-channel structure, GAA structure, and LGAA structure, the channel formation region that is formed at the interface between the oxide 530 and the gate insulator or in the vicinity of the interface can spread throughout the entire bulk of the oxide 530. Accordingly, the density of current flowing through the transistor can be increased, which can be expected to improve the on-state current of the transistor or increase the field-effect mobility of the transistor.

The conductor 503 has a structure similar to that of the conductor 518; a conductor 503a is formed in contact with an inner wall of the opening in the insulator 514 and the insulator 516, and a conductor 503b is formed on the inner side. Although the conductor 503a and the conductor 503b are stacked in the transistor 500, the present invention is not limited thereto. For example, the conductor 503 may have a single-layer structure or a stacked-layer structure of three or more layers.

Here, for the conductor 503a, it is preferable to use a conductive material that has a function of inhibiting diffusion of impurities such as a hydrogen atom, a hydrogen molecule, a water molecule, and a copper atom (a conductive material through which the impurities are less likely to pass). Alternatively, it is preferable to use a conductive material that has a function of inhibiting diffusion of oxygen (e.g., at least one of an oxygen atom, an oxygen molecule, and the like) (a conductive material through which the above oxygen is less likely to pass). Note that in this specification, the function of inhibiting diffusion of impurities or oxygen means a function of inhibiting diffusion of any one or all of the above impurities and the above oxygen.

For example, when the conductor 503a has a function of inhibiting diffusion of oxygen, a reduction in conductivity of the conductor 503b due to oxidation can be inhibited.

In the case where the conductor 503 also functions as a wiring, the conductor 503b is preferably formed using a conductive material with high conductivity that includes tungsten, copper, or aluminum as its main component. Although the conductor 503 is illustrated to have a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator including oxygen more than that in the stoichiometric composition is preferably used as the insulator 524 in contact with the oxide 530. Such oxygen is easily released from the film by heating. In this specification and the like, oxygen released by heating is sometimes referred to as excess oxygen. That is, a region including excess oxygen (also referred to as an “excess-oxygen region”) is preferably formed in the insulator 524. When such an insulator including excess oxygen is provided in contact with the oxide 530, oxygen vacancies (Vo) in the oxide 530 can be reduced and the reliability of the transistor 500 can be increased. Note that when hydrogen enters the oxygen vacancies in the oxide 530, such defects (hereinafter referred to as VoH in some cases) serve as donors and generate electrons serving as carriers in some cases. In other cases, bonding of part of hydrogen to oxygen bonded to a metal atom generates electrons serving as carriers. Thus, a transistor including an oxide semiconductor that includes a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen. In one embodiment of the present invention, VoH in the oxide 530 is preferably reduced as much as possible so that the oxide 530 becomes a highly purified intrinsic or substantially highly purified intrinsic oxide. In order to obtain such an oxide semiconductor with sufficiently reduced VoH, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). When an oxide semiconductor with sufficiently reduced impurities such as VoH is used for a channel formation region of a transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

Any one or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when reaction in which a bond of VoH is cut occurs, i.e., reaction of “VoH→Vo+H” occurs. Part of hydrogen generated at this time is bonded to oxygen and is removed as H₂O from the oxide 530 or an insulator in the vicinity of the oxide 530 in some cases. Some hydrogen may be gettered into the conductors 542a and 542b in some cases.

For the microwave treatment, for example, an apparatus including a power supply that generates high-density plasma or an apparatus including a power supply that applies RF to the substrate side is suitably used. For example, the use of an oxygen-including gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The microwave treatment is performed under a pressure of 133 Pa or higher, preferably 200 Pa or higher, further preferably 400 Pa or higher. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In the manufacturing process of the transistor 500, the heat treatment is preferably performed with the surface of the oxide 530 exposed. For example, the heat treatment is performed at a temperature higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere including an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 530 to reduce oxygen vacancies (Vo). Alternatively, the heat treatment may be performed under reduced pressure. Alternatively, the heat treatment may be performed in such a manner that heat treatment is performed in a nitrogen gas or inert gas atmosphere, and then another heat treatment is performed in an atmosphere including an oxidizing gas at higher than or equal to 10 ppm, higher than or equal to 1%, or higher than or equal to 10% in order to compensate for released oxygen. Alternatively, the heat treatment may be performed in such a manner that heat treatment is performed in an atmosphere including an oxidizing gas at higher than or equal to 10 ppm, higher than or equal to 1%, or higher than or equal to 10%, and then another heat treatment is successively performed in a nitrogen gas or inert gas atmosphere.

Note that oxygen adding treatment performed on the oxide 530 can promote reaction in which oxygen vacancies in the oxide 530 are filled with supplied oxygen, i.e., reaction of “Vo+O→null.” Furthermore, hydrogen remaining in the oxide 530 reacts with supplied oxygen, so that the hydrogen can be removed as H2O (dehydration). This can inhibit recombination of hydrogen remaining in the oxide 530 with oxygen vacancies and formation of VoH.

In the case where the insulator 524 includes an excess-oxygen region, the insulator 522 preferably has a function of inhibiting diffusion of oxygen (e.g., oxygen atoms and oxygen molecules) (it is preferable that oxygen be less likely to pass through the insulator 522).

The insulator 522 preferably has a function of inhibiting diffusion of oxygen, impurities, or the like, in which case diffusion of oxygen included in the oxide 530 to the insulator 520 side is prevented. Furthermore, the conductor 503 can be inhibited from reacting with oxygen included in the insulator 524, the oxide 530, or the like.

The insulator 522 preferably has a single-layer structure or a stacked-layer structure using an insulator including what is called a high-k material such as aluminum oxide, hafnium oxide, an oxide including aluminum and hafnium (hafnium aluminate), tantalum oxide, zirconium oxide, lead zirconate titanate (PZT), strontium titanate (SrTiO₃), or (Ba,Sr)TiO₃ (BST), for example. As miniaturization and high integration of transistors progress, a problem such as off-state current might arise because of a thinner gate insulating film. When a high-k material is used for an insulator functioning as the gate insulating film, a gate potential during transistor operation can be reduced while the physical thickness is maintained.

It is particularly preferable to use an insulator including an oxide of one or both of aluminum and hafnium, which is an insulating material having a function of inhibiting diffusion of impurities, oxygen, and the like (an insulating material through which the above oxygen is less likely to pass). Aluminum oxide, hafnium oxide, an oxide including aluminum and hafnium (hafnium aluminate), or the like is preferably used for the insulator including an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

It is preferable that the insulator 520 be thermally stable. For example, silicon oxide and silicon oxynitride are preferred because of their thermal stability. Furthermore, a combination of an insulator that is a high-k material and silicon oxide or silicon oxynitride enables the insulator 520 to have a stacked-layer structure that has thermal stability and high relative permittivity.

Note that the transistor 500 in FIG. 10A and FIG. 10B includes the insulator 520, the insulator 522, and the insulator 524 as the second gate insulating film having a three-layer structure; however, the second gate insulating film may have a single-layer structure, a two-layer structure, or a stacked-layer structure of four or more layers. In such a case, the stacked layers are not necessarily formed of the same material and may be formed of different materials.

In the transistor 500, a metal oxide functioning as an oxide semiconductor is used as the oxide 530 including the channel formation region.

The metal oxide functioning as an oxide semiconductor may be formed by a sputtering method or an ALD (Atomic Layer Deposition) method. In the case where the oxide semiconductor is formed by a sputtering method, the film density can be increased. Meanwhile, in the case where the oxide semiconductor is deposited by an ALD method, coverage or controllability of a thickness (typically, less than or equal to 10 nm, preferably greater than or equal to 1 nm and less than or equal to 5 nm) can be improved. Alternatively, the crystallinity of the oxide semiconductor may be improved by plasma treatment or microwave treatment after formation of the oxide semiconductor. Here, in this specification and the like, the microwave treatment refers to, for example, treatment using an apparatus including a power source that generates high-density plasma with use of a microwave. In this specification and the like, the microwave refers to an electromagnetic wave having a frequency greater than or equal to 300 MHz and less than or equal to 300 GHz. Note that the metal oxide functioning as an oxide semiconductor will be described in detail in another embodiment.

The metal oxide functioning as the channel formation region in the oxide 530 has a band gap of preferably 2 eV or more, further preferably 2.5 eV or more. The use of a metal oxide having such a wide band gap can reduce the off-state current of the transistor.

When the oxide 530 includes the oxide 530a under the oxide 530b, it is possible to inhibit diffusion of impurities into the oxide 530b from the components formed below the oxide 530a.

Note that the oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To change the energy level gradually, the density of defect states in a mixed layer formed at the interface between the oxide 530a and the oxide 530b is preferably made low.

Specifically, when the oxide 530a and the oxide 530b include a common element (as a main component) in addition to oxygen, a mixed layer with a low density of defect states can be formed. For example, in the case where the oxide 530b is an In-Ga-Zn oxide, an In-Ga-Zn oxide, a Ga-Zn oxide, gallium oxide, or the like is preferably used for the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including any of the above metal elements as its component; an alloy including a combination of the above metal elements; or the like. For example, it is preferable to use tantalum nitride, titanium nitride, tungsten, a nitride including titanium and aluminum, a nitride including tantalum and aluminum, ruthenium oxide, ruthenium nitride, an oxide including strontium and ruthenium, an oxide including lanthanum and nickel, or the like. Tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

Although the conductor 542a and the conductor 542b have a single-layer structure in FIG. 10A, they may have a stacked-layer structure of two or more layers. For example, it is preferable to stack a tantalum nitride film and a tungsten film. Alternatively, a titanium film and an aluminum film may be stacked. Other examples include a two-layer structure where an aluminum film is stacked over a tungsten film, a two-layer structure where a copper film is stacked over a copper-magnesium-aluminum alloy film, a two-layer structure where a copper film is stacked over a titanium film, and a two-layer structure where a copper film is stacked over a tungsten film.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material including indium oxide, tin oxide, or zinc oxide may be used.

As illustrated in FIG. 10A, a region 543a and a region 543b are sometimes formed as low-resistance regions at and near the interface between the oxide 530 and the conductor 542a (the conductor 542b). In that case, the region 543a functions as one of a source region and a drain region, and the region 543b functions as the other of the source region and the drain region. The channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that includes the metal included in the conductor 542a (the conductor 542b) and the component of the oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover a side surface of the oxide 530 and to be in contact with the insulator 524.

A metal oxide including one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use, as the insulator 544, an insulator including an oxide of one or both of aluminum and hafnium, such as aluminum oxide, hafnium oxide, or an oxide including aluminum and hafnium (hafnium aluminate). In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

The insulator 544 can inhibit impurities such as water and hydrogen included in the insulator 580 from diffusing into the oxide 530b. Moreover, the oxidation of the conductors 542a and 542b due to excess oxygen included in the insulator 580 can be inhibited.

The insulator 545 functions as a first gate insulating film. Like the insulator 524, the insulator 545 is preferably formed using an insulator that includes excess oxygen and releases oxygen by heating.

Specifically, it is possible to use any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide each including excess oxygen. In particular, silicon oxide and silicon oxynitride, which have thermal stability, are preferable.

When an insulator including excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen included in the insulator 545 to the oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as off-state current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 functioning as the first gate electrode has a two-layer structure in FIG. 10A and FIG. 10B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, the conductivity of the conductor 560b can be inhibited from being lowered because of oxidation due to oxygen included in the insulator 545. As a conductive material having a function of inhibiting diffusion of oxygen, for example, tantalum, tantalum nitride, ruthenium, ruthenium oxide, or the like is preferably used. Alternatively, the conductor 560a can be formed using an oxide semiconductor that can be used for the oxide 530. In that case, when the conductor 560b is deposited by a sputtering method, the conductor 560a can have a reduced electrical resistance and become a conductor. Such a conductor can be referred to as an OC (Oxide Conductor) electrode.

The conductor 560b is preferably formed using a conductive material including tungsten, copper, or aluminum as its main component. The conductor 560b also functions as a wiring and thus is preferably formed using a conductor having high conductivity. For example, a conductive material including tungsten, copper, or aluminum as its main component can be used. The conductor 560b may have a stacked-layer structure, for example, a stacked-layer structure of titanium or titanium nitride and the above conductive material.

The insulator 580 is provided over the conductor 542a and the conductor 542b with the insulator 544 therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride, which have thermal stability, are preferable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is deposited by a sputtering method, excess-oxygen regions can be provided in the insulator 545 and the insulator 580. Accordingly, oxygen can be supplied from the excess-oxygen regions to the oxide 530.

For example, a metal oxide including one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

An insulator 581 functioning as an interlayer film is preferably provided over the insulator 574. As in the insulator 524 or the like, the concentration of impurities such as water or hydrogen in the insulator 581 is preferably reduced.

A conductor 540a and a conductor 540b are positioned in openings formed in the insulator 581, the insulator 574, the insulator 580, and the insulator 544. The conductor 540a and the conductor 540b are provided to face each other with the conductor 560 therebetween. The conductor 540a and the conductor 540b have a structure similar to that of a conductor 546 and a conductor 548 described later.

An insulator 582 is provided over the insulator 581. A substance having a barrier property against oxygen, hydrogen, or the like is preferably used for the insulator 582. Thus, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents passage of both oxygen and impurities such as hydrogen and moisture that cause a change in electrical characteristics of the transistor. Accordingly, aluminum oxide can prevent mixing of impurities such as hydrogen and moisture into the transistor 500 during and after the manufacturing process of the transistor. In addition, release of oxygen from the oxide included in the transistor 500 can be inhibited. Thus, aluminum oxide is suitably used for a protective film of the transistor 500.

An insulator 586 is provided over the insulator 582. For the insulator 586, a material similar to that for the insulator 320 can be used. Furthermore, when a material with comparatively low permittivity is used for these insulators, parasitic capacitance generated between wirings can be reduced. For example, a silicon oxide film, a silicon oxynitride film, or the like can be used for the insulator 586.

The conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be formed using a material similar to that for the conductor 328 and the conductor 330.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the manufacturing steps of the transistor 500. Note that for the insulator having a high barrier property against hydrogen or water, a material similar to that for the insulator 522 or the insulator 514 can be used, for example.

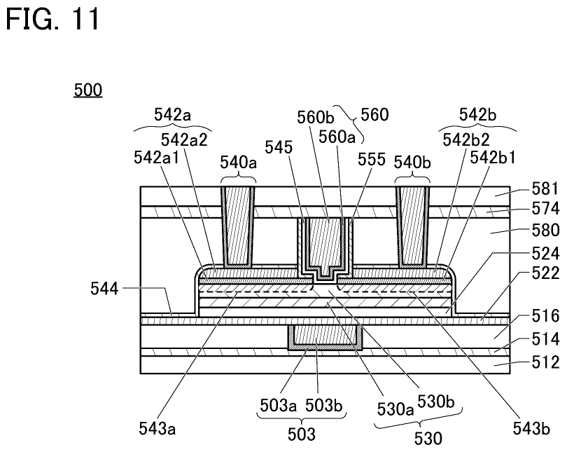

Note that the transistor that can be used in the present invention is not limited to the transistor 500 illustrated in FIG. 10A and FIG. 10B. For example, the transistor 500 having a structure illustrated in FIG. 11 may be used. The transistor 500 illustrated in FIG. 11 is different from the transistor illustrated in FIG. 10A and FIG. 10B in that an insulator 555 is used and that the conductor 542a (a conductor 542a1 and a conductor 542a2) and the conductor 542b (a conductor 542b1 and a conductor 542b2) each have a stacked-layer structure.

The conductor 542a has a stacked-layer structure of the conductor 542a1 and the conductor 542a2 over the conductor 542a1, and the conductor 542b has a stacked-layer structure of the conductor 542b1 and the conductor 542b2 over the conductor 542b1. The conductor 542a1 and the conductor 542b1 in contact with the oxide 530b are preferably conductors that are less likely to be oxidized, such as a metal nitride. Thus, excessive oxidation of the conductor 542a and the conductor 542b due to oxygen included in the oxide 530b can be prevented. Moreover, the conductor 542a2 and the conductor 542b2 are preferably conductors having higher conductivity than the conductor 542a1 and the conductor 542b1, such as a metal layer. Thus, the conductor 542a and the conductor 542b can function as wirings or electrodes having high conductivity. In this manner, it is possible to provide a semiconductor device in which the conductor 542a and the conductor 542b that function as wirings or electrodes are provided in contact with the top surface of the oxide 530 functioning as an active layer.

As the conductors 542l1 and 542b1, a metal nitride is preferably used; for example, a nitride including tantalum, a nitride including titanium, a nitride including molybdenum, a nitride including tungsten, a nitride including tantalum and aluminum, or a nitride including titanium and aluminum is preferably used. In one embodiment of the present invention, a nitride including tantalum is particularly preferable. As another example, ruthenium, ruthenium oxide, ruthenium nitride, an oxide including strontium and ruthenium, or an oxide including lanthanum and nickel may be used. These materials are preferable because they are each a conductive material that is less likely to be oxidized or a material that maintains the conductivity even after absorbing oxygen.

The conductor 542a2 and the conductor 542b2 preferably have higher conductivity than the conductor 542a1 and the conductor 542b1. For example, the thicknesses of the conductor 542a2 and the conductor 542b2 are preferably larger than the thicknesses of the conductor 542a1 and the conductor 542b1. For the conductor 542a2 and the conductor 542b2, a conductor that can be used for the conductor 560b can be used. The above structure can reduce the resistance of the conductor 542a2 and the conductor 542b2.

For example, tantalum nitride or titanium nitride can be used for the conductor 542a1 and the conductor 542b1, and tungsten can be used for the conductor 542a2 and the conductor 542b2.

As illustrated in FIG. 11, in a cross-sectional view of the transistor 500 in the channel length direction, the distance between the conductor 542a1 and the conductor 542b1 is smaller than the distance between the conductor 542a2 and the conductor 542b2. With such a structure, the distance between the source and the drain can be shortened, and the channel length can be accordingly shortened. Thus, the frequency characteristics of the transistor 500 can be improved. In this manner, miniaturization of the semiconductor device enables the semiconductor device to have a higher operating speed.

The insulator 555 is preferably an insulator that is less likely to be oxidized, such as a nitride. The insulator 555 is formed in contact with a side surface of the conductor 542a2 and a side surface of the conductor 542b2 and has a function of protecting the conductor 542a2 and the conductor 542b2. The insulator 555 is exposed to an oxidized atmosphere, and thus is preferably an inorganic insulator that is less likely to be oxidized. Since the insulator 555 is in contact with the conductor 542a2 and the conductor 542b2, the insulator 555 is preferably an inorganic insulator that is less likely to oxidize the conductors 542a2 and 542b2. Therefore, for the insulator 555, an insulating material having a barrier property against oxygen is preferably used. For example, silicon nitride can be used for the insulator 555.

The transistor 500 illustrated in FIG. 11 is formed in the following manner: an opening is formed in the insulator 580 and the insulator 544, the insulator 555 is formed in contact with a sidewall of the opening, and then the conductor 542a1 and the conductor 542b1 are separated using a mask. Here, the opening overlaps with a region between the conductor 542a2 and the conductor 542b2. The conductor 542a1 and the conductor 542b1 are formed to partly extend in the opening. Thus, in the opening, the insulator 555 is in contact with the top surface of the conductors 542a1, the top surface of the conductor 542b1, a side surface of the conductor 542a2, and a side surface of the conductor 542b2. The insulator 545 is in contact with the top surface of the oxide 530 in a region between the conductor 542a1 and the conductor 542b1.

Heat treatment in an atmosphere including oxygen is preferably performed after the separation of the conductor into the conductor 542a1 and the conductor 542b1 and before the deposition of the insulator 545. Thus, oxygen can be supplied to the oxide 530a and the oxide 530b to reduce oxygen vacancies. Furthermore, since the insulator 555 is formed in contact with the side surface of the conductor 542a2 and the side surface of the conductor 542b2, excessive oxidation of the conductor 542a2 and the conductor 542b2 can be prevented. Accordingly, the transistor can have favorable electrical characteristics and higher reliability. In addition, variations in electrical characteristics of transistors formed over the same substrate can be reduced. In the transistor 500, the insulator 524 may be formed into an island shape, as illustrated in FIG. 11. Here, the insulator 524 may be formed such that its side end portion is substantially aligned with a side end portion of the oxide 530.

In the transistor 500, the insulator 522 may be in contact with the insulator 516 and the conductor 503, as illustrated in FIG. 11. In other words, the insulator 520 illustrated in FIG. 10A and FIG. 10B may be omitted.

Next, the capacitor 600 is provided above the transistor 500. The capacitor 600 includes a conductor 610, a conductor 620, and an insulator 630.

A conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, it is possible to use a metal film including an element selected from molybdenum, titanium, tantalum, tungsten, aluminum, copper, chromium, neodymium, and scandium; a metal nitride film including the above element as its component (a tantalum nitride film, a titanium nitride film, a molybdenum nitride film, or a tungsten nitride film); or the like. Alternatively, it is possible to employ a conductive material such as indium tin oxide, indium oxide including tungsten oxide, indium zinc oxide including tungsten oxide, indium oxide including titanium oxide, indium tin oxide including titanium oxide, indium zinc oxide, or indium tin oxide to which silicon oxide is added.

Although the conductor 612 and the conductor 610 each have a single-layer structure in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In the case where the conductor 620 is formed at the same time as another component such as a conductor, copper (Cu), aluminum (Al), or the like, which is a low-resistance metal material, is used.

An insulator 640 is provided over the conductor 620 and the insulator 630. The insulator 640 can be formed using a material similar to that for the insulator 320. The insulator 640 may function as a planarization film that covers an uneven shape therebelow.

With the use of this structure, a semiconductor device using a transistor including an oxide semiconductor can be miniaturized or highly integrated.

As a substrate that can be used for the semiconductor device of one embodiment of the present invention, a glass substrate, a quartz substrate, a sapphire substrate, a ceramic substrate, a metal substrate (e.g., a stainless steel substrate, a substrate including stainless steel foil, a tungsten substrate, a substrate including tungsten foil, or the like), a semiconductor substrate (e.g., a single crystal semiconductor substrate, a polycrystalline semiconductor substrate, a compound semiconductor substrate, or the like), an SOI (silicon on Insulator) substrate, or the like can be used. Alternatively, a plastic substrate having heat resistance to the processing temperature in this embodiment may be used. Examples of the glass substrate include barium borosilicate glass, aluminosilicate glass, aluminoborosilicate glass, and soda lime glass. Alternatively, crystallized glass or the like can be used.

Note that the transistor 550 illustrated in FIG. 9 is just an example and is not limited to the structure illustrated therein, and an appropriate transistor can be used in accordance with a circuit structure, a driving method, or the like. For example, when the semiconductor device is a single-polarity circuit that is composed of only OS transistors (which means transistors having the same polarity, e.g., only n-channel transistors), the transistor 550 has a structure similar to that of the transistor 500.

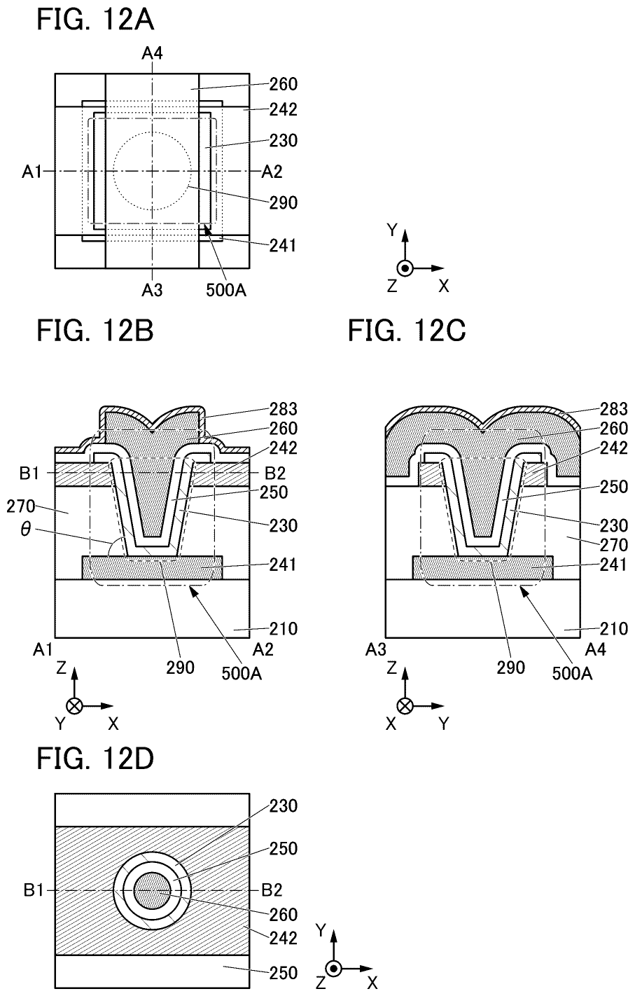

Note that the transistor that can be used in the present invention is not limited to the transistor 500 illustrated in FIG. 10A, FIG. 10B, and FIG. 11. For example, the transistor 500A having a structure illustrated in FIG. 12A to FIG. 12D may be used. The transistor 500A illustrated in FIG. 12A to FIG. 12D is different from the transistor illustrated in FIG. 10A and FIG. 10B in being a vertical-channel transistor.

FIG. 12A to FIG. 12D are tops views and cross-sectional views illustrating a structure example of a transistor. FIG. 12A is a top view of the transistor 500A. FIG. 12B is a cross-sectional view of a portion indicated by the dashed-dotted line A1-A2 in FIG. 12A, and FIG. 12C is a cross-sectional view of a portion indicated by the dashed-dotted line A3-A4 in FIG. 12A. FIG. 12D is a top view of a portion indicated by the dashed-dotted line B1-B2 in FIG. 12D. Note that for clarity of the drawing, some components are not illustrated in the top views of FIG. 12A and FIG. 12D.

The transistor 500A includes a conductor 241 and an insulator 270 over an insulator 210, a metal oxide 230 over the conductor 241, an insulator 250 over the metal oxide 230, a conductor 260 over the insulator 250, a conductor 242 over the insulator 270, and an insulator 272 over the insulator 270 and the conductor 242.

The conductor 241 includes a region functioning as one of a source electrode and a drain electrode of the transistor 500A, the conductor 242 includes a region functioning as the other of the source electrode and the drain electrode of the transistor 500A, and the conductor 260 includes a region functioning as a gate electrode of the transistor 500A. The metal oxide 230 includes a region functioning as a channel formation region.

For the metal oxide 230, any of the materials described as the oxide 530a and the oxide 530b can be used.

The metal oxide 230 includes a channel formation region of the transistor 500A and a source region and a drain region provided to sandwich the channel formation region. At least part of the channel formation region overlaps with the conductor 260. The source region overlaps with one of the conductor 241 and the conductor 242, and the drain region overlaps with the other of the conductor 241 and the conductor 242.

An opening reaching the conductor 241 is provided in the conductor 242 and the insulator 270. In addition, the opening includes a region overlapping with the conductor 241 in the top view. At least part of the metal oxide 230, part of the insulator 250, and part of the conductor 260 are placed in the opening. Note that the opening can be regarded as including an opening included in the conductor 242 and an opening included in the insulator 270. It can be said that the conductor 242 has an opening overlapping with the conductor 241 in the top view.

The metal oxide 230 is provided in contact with the side surface and the bottom surface of the opening portion 290 provided in the conductor 242 and the insulator 270. In other words, the metal oxide 230 includes a region in contact with the side surface of the opening portion 290 included in the conductor 242 and each of the top surfaces of the conductors 241 and 242. The metal oxide 230 includes a concave portion. The concave portion includes a region overlapping with the opening portion 290 included in the conductor 242 in the top view.

At least part of the insulator 250 is provided in a concave portion of the metal oxide 230. The insulator 250 includes a region in contact with the top surface of the metal oxide 230. The insulator 250 includes a concave portion. The concave portion is positioned inside the concave portion of the metal oxide 230.

The conductor 260 is provided to fill the concave portion of the insulator 250. The conductor 260 includes a region in contact with the top surface of the insulator 250. The conductor 260 includes a region overlapping with the metal oxide 230 with the insulator 250 therebetween in a region between the conductor 241 and the conductor 242 in the cross-sectional view. Note that the conductor 260 whose bottom portion has a needle-like shape may be referred to as a needle-shaped gate.

The sidewall of the opening portion 290 preferably has a tapered shape. When the sidewall of the opening portion 290 has a tapered shape, the coverage with the metal oxide 230, the insulator 250, or the like can be improved, so that defects such as voids can be reduced. For example, the angle formed between the side surface of the insulator 270 and the top surface of the conductor 241 (the angle θ illustrated in FIG. 12B) in the opening portion 290 is preferably greater than or equal to 45° and less than or equal to 90°. Alternatively, the angle is preferably greater than or equal to 45° and less than or equal to 75°. Alternatively, the angle is preferably greater than or equal to 45° and less than or equal to 650. Note that when the sidewall of the opening portion 290 is greater than or equal to 85° and less than or equal to 90°, the transistor is suitably miniaturized.

Note that in this specification and the like, the tapered shape refers to a shape such that at least part of a side surface of a component is inclined to a substrate surface or a formation surface. For example, there is a region where the angle formed between the inclined side surface and the substrate surface (hereinafter, the angle is sometimes referred to as a taper angle) is less than or equal to 90°. Note that the side surface of the component and the substrate surface are not necessarily completely flat and may be substantially flat with a slight curvature or substantially flat with slight unevenness.

In the above structure, the channel length of the transistor 500A is the distance from the top surface of the conductor 241 to the bottom surface of the conductor 242 in the cross-sectional view, and is determined by the thickness of the insulator 270 and the angle θ in the opening portion 290 in a region overlapping with the conductor 241. In other words, the channel length of the transistor 500A can be adjusted by the thickness of the insulator 270 and the angle θ in the opening portion 290 in the region overlapping with the conductor 241. For example, when the thickness of the insulator 270 is made small, the transistor 500A having a short channel length can be manufactured.

In the above structure, the channel width of the transistor 500A is the length of a region where the insulator 270 and the metal oxide 230 are in contact with each other in the top view, and is also the length of the outline (outer periphery) of the metal oxide 230 in the top view. That is, the channel width of the transistor 500A can be adjusted by changing the diameter of the opening provided in the insulator 270. For example, when the diameter of the opening is made large, the transistor 500A can have a large channel width. Note that the opening can be rephrased as an opening in which some components of the transistor 500A (here, the metal oxide 230, the insulator 250, and the conductor 260) are provided.

The transistor 500A has a structure in which the channel formation region surrounds the gate electrode. Thus, the transistor 500A can be referred to as a transistor having a CAA (Channel-All-Around) structure.

Although FIG. 12D illustrates a structure where the top surface of the opening included in the conductor 242 has a circular shape, the present invention is not limited thereto. For example, the top surface of the opening included in the conductor 242 may have an oval shape, a polygonal shape, or a polygonal shape with rounded corners. The polygonal shape here means a triangle, a quadrangle, a pentagon, a hexagon, and the like.

The insulator 250 may have either a single-layer structure or a stacked-layer structure.

As the insulator 250, for example, silicon oxide, silicon oxynitride, silicon oxide to which fluorine is added, silicon oxide to which carbon is added, silicon oxide to which carbon and nitrogen are added, porous silicon oxide, or the like. In particular, silicon oxide and silicon oxynitride, which are thermally stable, are preferable. The insulator 250 in this case is an insulator including at least oxygen and silicon.

The concentration of impurities such as water and hydrogen in the insulator 250 is preferably reduced.

Note that an insulator having a barrier property against oxygen may be provided between the insulator 250 and the metal oxide 230. The insulator is provided in contact with the bottom surface of the insulator 250 and the concave portion of the metal oxide 230. When the insulator has a barrier property against oxygen, oxygen included in the insulator 250 can be supplied to the channel formation region, while oxygen included in the insulator 250 can be inhibited from being excessively supplied to the channel formation region. Thus, it is possible to inhibit release of oxygen from the metal oxide 230 when heat treatment or the like is performed and inhibit formation of oxygen vacancies in the metal oxide 230. Thus, the transistor 500A can have favorable electrical characteristics and higher reliability.

An insulator including an oxide of one or both of aluminum and hafnium is preferably used as the above insulator. As the insulator, aluminum oxide, hafnium oxide, an oxide including aluminum and hafnium (hafnium aluminate), an oxide including hafnium and silicon (hafnium silicate), or the like can be used. As the above insulator, aluminum oxide is further preferably used. In this case, the above insulator is an insulator including at least oxygen and aluminum. Note that oxygen is less likely to pass through the above insulator than the insulator 250, for example. For the above insulator, a material through which oxygen is less likely to pass than the insulator 250 is used, for example. For the above insulator, magnesium oxide, gallium oxide, gallium zinc oxide, or indium gallium zinc oxide may be used, for example.

FIG. 12B illustrates a structure in which the conductor 260 is a single layer. Note that the conductor 260 may have a stacked-layer structure. For example, the conductor 260 preferably includes a first conductor, and a second conductor over the first conductor. Specifically, the first conductor of the conductor 260 is preferably placed to cover the bottom surface and the side surface of the second conductor of the conductor 260.

For the first conductor of the conductor 260, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like). Alternatively, it is preferable to use a conductive material which is not easily oxidized.

When the first conductor of the conductor 260 has a function of inhibiting oxygen diffusion, for example, the conductivity of the second conductor of the conductor 260 can be inhibited from being lowered because of oxidation due to oxygen included in the insulator 250. As the conductive material having a function of inhibiting oxygen diffusion, for example, titanium, titanium nitride, tantalum, tantalum nitride, ruthenium, or ruthenium oxide is preferably used.

An insulator 283 is provided over the insulator 250. As the insulator 283, an insulator having a barrier property against hydrogen is preferably used. This can inhibit diffusion of hydrogen into the metal oxide 230 from the outside of the transistor 500A through the insulator 250. Each of a silicon nitride film and a silicon nitride oxide film can be suitably used as the insulator 283 because the amount of impurities (e.g., water and hydrogen) released from the silicon nitride film and the silicon nitride oxide film themselves is small and have a feature that oxygen and hydrogen are less likely to be transmitted.

The configuration, structure, method, and the like described in this embodiment can be used in combination as appropriate with the configurations, structures, methods, and the like described in the other embodiments, an example, and the like.

### Embodiment 4

In this embodiment, a cross-sectional structure example of a semiconductor device including the OS transistor described in the above embodiments, are described.

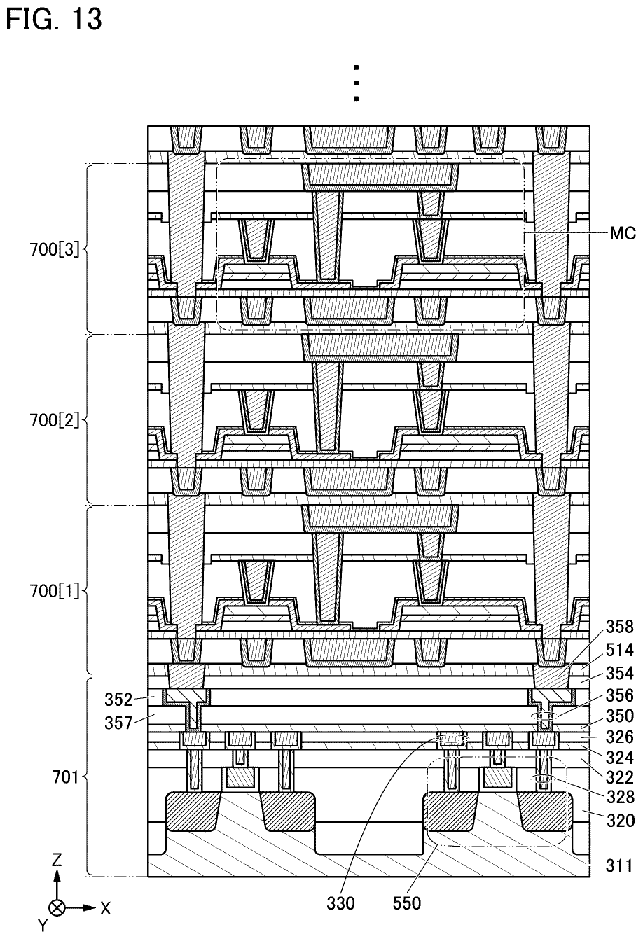

FIG. 13 illustrates a cross-sectional structure example of the case of using a NOSRAM circuit structure. In the example illustrated in FIG. 13, a memory layer 700[1] to a memory layer 700[3] are stacked over the driver circuit layer 701.

FIG. 13 also illustrates an example of the transistor 550 included in the driver circuit layer 701. As the transistor 550, the transistor 550 described in the above embodiment can be used.

Note that the transistor 550 illustrated in FIG. 13 is an example and is not limited to the structure illustrated therein; an appropriate transistor can be used in accordance with a circuit structure or a driving method.

A wiring layer provided with an interlayer film, a wiring, a plug, and the like may be provided between the driver circuit layer 701 and the memory layers 700 or between a k-th memory layer 700 and a (k+1)th memory layer 700. Note that in this embodiment and the like, the k-th memory layer 700 is denoted as a memory layer 700[k] and the (k+1)th memory layer 700 is denoted as a memory layer 700[k+1] in some cases. Here, k is an integer greater than or equal to 1 and less than or equal to N. In addition, in this embodiment and the like, the solutions of “k+α (α is an integer greater than or equal to 1)” and “k−α” are each an integer greater than or equal to 1 and less than or equal to N.

A plurality of wiring layers can be provided in accordance with the design. Moreover, in this specification and the like, a wiring and a plug electrically connected to the wiring may be a single component. That is, part of a conductor functions as a wiring in some cases and part of a conductor functions as a plug in other cases.

For example, the insulator 320, the insulator 322, the insulator 324, and the insulator 326 are sequentially stacked and provided over the transistor 550 as interlayer films. The conductor 328 and the like are embedded in the insulator 320 and the insulator 322. The conductor 330 and the like are embedded in the insulator 324 and the insulator 326. Note that the conductor 328 and the conductor 330 each function as a contact plug or a wiring.

The insulator functioning as an interlayer film may function as a planarization film that covers an uneven shape thereunder. For example, a top surface of the insulator 320 may be planarized by planarization treatment using a chemical mechanical polishing (CMP) method to increase planarity.

A wiring layer may be provided over the insulator 326 and the conductor 330. For example, in FIG. 13, the insulator 350, an insulator 357, the insulator 352, and the insulator 354 are sequentially stacked and provided over the insulator 326 and the conductor 330. The conductor 356 is formed in the insulator 350, the insulator 357, and the insulator 352. The conductor 356 functions as a contact plug or a wiring.

The insulator 514 included in the memory layer 700[1] is provided over the insulator 354. A conductor 358 is embedded in the insulator 514 and the insulator 354. The conductor 358 functions as a contact plug or a wiring. For example, the wiring WBL (or the wiring RBL) and the transistor 550 are electrically connected to each other through the conductor 358, the conductor 356, the conductor 330, and the like.

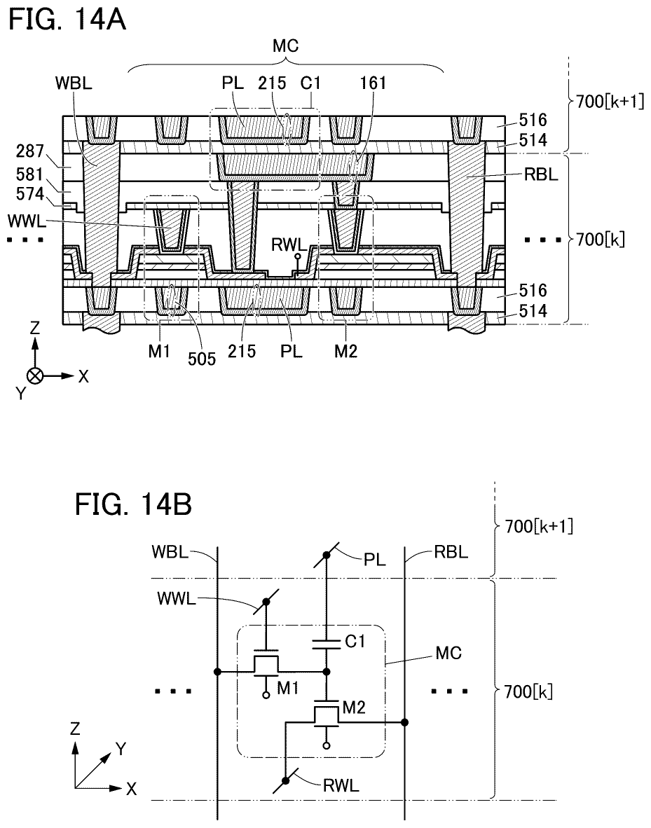

FIG. 14A illustrates a cross-sectional structure example of the memory layer 700[k]. In addition, FIG. 14B illustrates an equivalent circuit diagram of FIG. 14A.

The memory cell MC illustrated in FIG. 13 and FIG. 14A includes the transistor M1 and the transistor M2 over the insulator 514. For example, the transistor 500 illustrated in the above embodiment can be used as the transistors M1 and M2. A conductor 215 is provided over the insulator 514. The conductor 215 and the conductor 505 can be concurrently formed using the same material in the same step.

Note that in this embodiment, a variation example of the transistor 500 is illustrated as the transistors M1 and M2. Specifically, the transistors M1 and M2 are different from the transistor 500 in that the conductor 542a and the conductor 542b extend beyond an end portion of an oxide 531 (an oxide 530a and an oxide 530b).

In the memory cell MC illustrated in FIG. 13 and FIG. 14A, an insulator 287 is provided over the insulator 581, and a conductor 161 is embedded in the insulator 287. The insulator 514 of the memory layer 700[k+1] is provided over the insulator 287 and the conductor 161.

In FIG. 13 and FIG. 14A, the conductor 215 of the memory layer 700[k+1] functions as one terminal of the capacitor C, the insulator 514 of the memory layer 700[k+1] functions as a dielectric of the capacitor C, and the conductor 161 functions as the other terminal of the capacitor C. Note that PL in the drawing represents a wiring connected to the capacitor C. The other of the source and the drain of the transistor M1 is electrically connected to the conductor 161 through a contact plug. A gate of the transistor M2 is electrically connected to the conductor 161 through another contact plug. One of a source and a drain of the transistor M2 is electrically connected to the conductor 161 through another contact plug. The other of the source and the drain of the transistor M2 is electrically connected to the conductor 161 through another contact plug.

This embodiment can be implemented in combination with the other embodiments described in this specification as appropriate.

### Embodiment 5

In this embodiment, a transistor whose channel formation region includes an oxide semiconductor (OS transistor) will be described. Note that in the description of the OS transistor, comparison with a transistor whose channel formation region includes silicon (also referred to as a Si transistor) will also be briefly described.

### OS Transistor

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, it is preferable that the impurity concentration in an adjacent film be also reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Accordingly, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor where the short-channel effect does not appear or hardly appears.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor, and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region become n⁺-type regions.

The OS transistor with the above structure can have favorable electrical characteristics even when a semiconductor device is miniaturized or highly integrated. For example, the semiconductor device can have favorable electrical characteristics even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Thus, an OS transistor can be used as a transistor with a short channel length more suitably than a Si transistor. Note that the gate length refers to the length of a gate electrode in a direction in which carriers move inside a channel formation region during operation of a transistor, and corresponds to the width of a bottom surface of the gate electrode in a plan view of the transistor.

Miniaturization of an OS transistor can improve the high frequency characteristics of the transistor. Specifically, the cutoff frequency of the transistor can be increased. When the gate length of the OS transistor is within any of the above ranges, the cutoff frequency of the transistor can be greater than or equal to 50 GHz, preferably greater than or equal to 100 GHz, further preferably greater than or equal to 150 GHz at room temperature, for example.

As described above, the OS transistor has advantageous effects over the Si transistor, such as lower off-state current and the capability of being manufactured with a shorter channel length.

The configuration, structure, method, and the like described in this embodiment can be used in combination as appropriate with the configurations, structures, methods, and the like described in the other embodiments and the like.

### Embodiment 6

This embodiment will describe an electronic component, an electronic device, a large computer, space equipment, and a data center (also referred to as a DC) that can use the semiconductor device described in the above embodiment. An electronic component, an electronic device, a large computer, space equipment, and a data center each using the semiconductor device of one embodiment of the present invention are effective in achieving high performance, e.g., reducing power consumption.

### Electronic Component

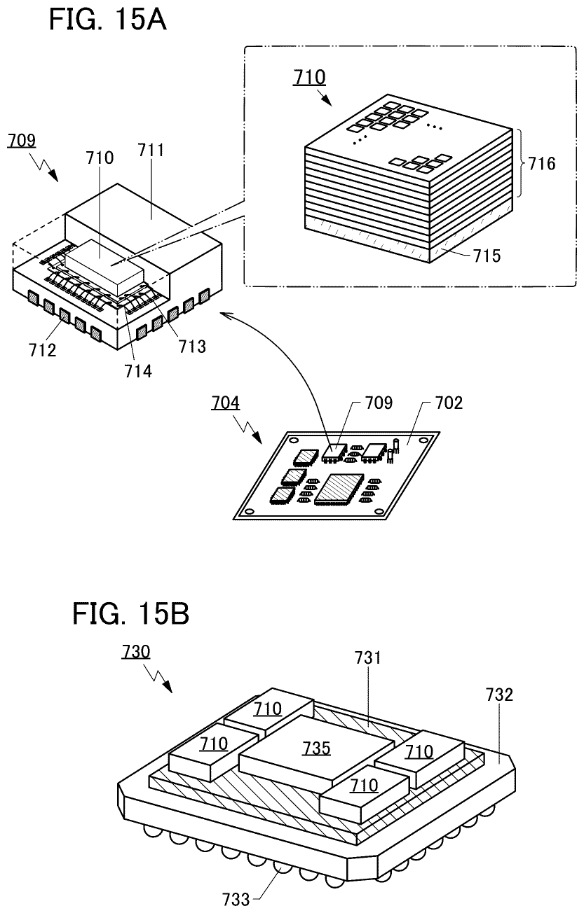

FIG. 15A is a perspective view of a substrate (a circuit board 704) on which an electronic component 709 is mounted. The electronic component 709 illustrated in FIG. 15A includes a semiconductor device 710 in a mold 711. Some components are omitted in FIG. 15A to show the inside of the electronic component 709. The electronic component 709 includes a land 712 outside the mold 711. The land 712 is electrically connected to an electrode pad 713, and the electrode pad 713 is electrically connected to the semiconductor device 710 through a wire 714. The electronic component 709 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that a bandwidth refers to a data transfer volume per unit time, and access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 15B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 15B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### Electronic Device

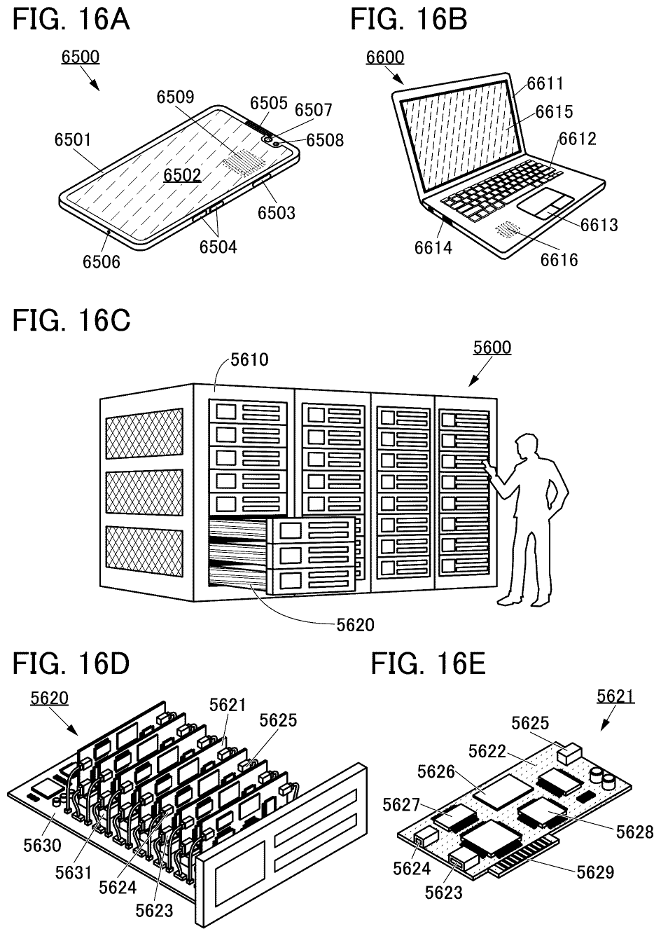

FIG. 16A is a perspective view of an electronic device 6500. The electronic device 6500 illustrated in FIG. 16A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a storage device, for example. The semiconductor device of one embodiment of the present invention can be used for the display portion 6502, the control device 6509, and the like.

An electronic device 6600 illustrated in FIG. 16B is an information terminal that can be used as a notebook personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a storage device, for example. The semiconductor device of one embodiment of the present invention can be used for the display portion 6615, the control device 6616, and the like. Note that the semiconductor device of one embodiment of the present invention is suitably used for the control device 6509 and the control device 6616, in which case power consumption can be reduced.

### Large Computer

FIG. 16C is a perspective view of a large computer 5600. In the large computer 5600 illustrated in FIG. 16C, a plurality of rack mount computers 5620 are stored in a rack 5610. Note that the large computer 5600 may be referred to as a supercomputer.

The computer 5620 can have a structure in a perspective view illustrated in FIG. 16D, for example. In FIG. 16D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 16E is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 16E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 709 can be used, for example.

The large computer 5600 can also function as a parallel computer. When the large computer 5600 is used as a parallel computer, large-scale computation necessary for artificial intelligence learning and inference can be performed, for example.

### Space Equipment

The semiconductor device of one embodiment of the present invention can be suitably used for space equipment such as equipment that processes and stores information.

The semiconductor device of one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in outer space.

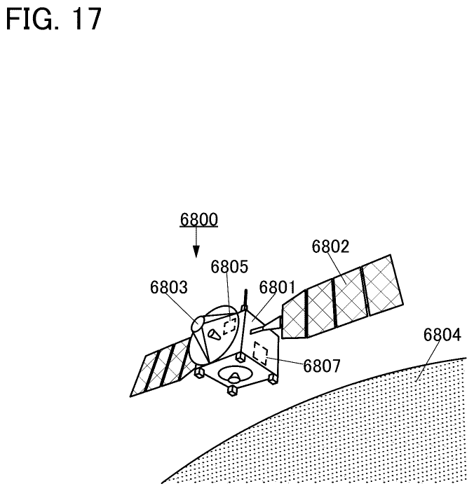

FIG. 17 illustrates an artificial satellite 6800 as an example of space equipment. The artificial satellite 6800 includes a body 6801, a solar panel 6802, an antenna 6803, a secondary battery 6805, and a control device 6807. Note that in FIG. 17, a planet 6804 in outer space is illustrated as an example. Note that outer space refers to, for example, space at an altitude greater than or equal to 100 km, and outer space in this specification may also include the thermosphere, mesosphere, and stratosphere.

Although not illustrated in FIG. 17, the secondary battery 6805 may be provided with a battery management system (also referred to as a BMS) or a battery control circuit. An OS transistor is suitably used in the battery management system or the battery control circuit because low power consumption and high reliability even in outer space are achieved.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a storage device, for example. Note that the semiconductor device of one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, the OS transistor has excellent effects of achieving wide memory bandwidth and being highly resistant to radiation as compared with the Si transistor.

### Data Center

The semiconductor device of one embodiment of the present invention can be suitably used for a storage system in a data center, for example. Long-term management of data, such as guarantee of data immutability, is required for the data center. The long-term management of data needs an increase in building size for, for example, setting a storage and a server for storing an enormous amount of data, ensuring stable power supply for data retention, and ensuring cooling equipment for data retention.

With the use of the semiconductor device of one embodiment of the present invention for the storage system used in the data center, electric power required for data retention can be reduced and a semiconductor device retaining data can be downsized. Thus, downsizing of the storage system, downsizing of the power supply for data retention, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

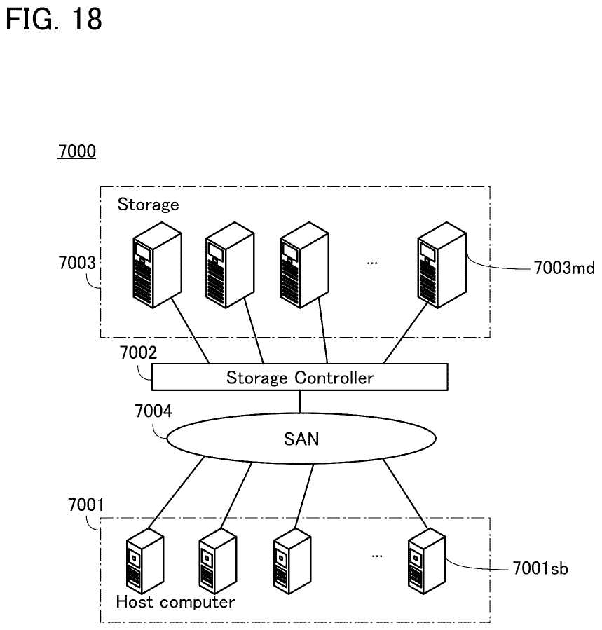

FIG. 18 illustrates a storage system that can be used in a data center. A storage system 7000 illustrated in FIG. 18 includes a plurality of servers 7001sb as a host 7001 (indicated as “Host Computer” in the diagram). The storage system 7000 includes a plurality of storage devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in the storage. In the storage system, in order to solve the problem of low access speed of the storage 7003, a cache memory is normally provided in the storage to shorten the time for data storage and output.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device of one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO2) can be reduced with the use of the semiconductor device of one embodiment of the present invention. The semiconductor device of one embodiment of the present invention can be effectively used as one of the global warming countermeasures because of its low power consumption.

The configuration, structure, method, and the like described in this embodiment can be used in combination as appropriate with the configurations, structures, methods, and the like described in the other embodiments and the like.

### Supplementary Notes on Description in This Specification and the Like

The following are notes on the description of the above embodiments and the structures in the embodiments.

One embodiment of the present invention can be constituted by combining, as appropriate, the structure described in each embodiment with the structures described in the other embodiments. In the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

In the drawings, the size, the layer thickness, or the region is shown with given magnitude for description convenience. Therefore, they are not limited to the illustrated scale. Note that the drawings are schematically shown for clarity, and embodiments of the present invention are not limited to shapes, values or the like shown in the drawings. For example, variations in signal, voltage, or current due to noise, variations in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relation of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes”or “wirings”are formed in an integrated manner, for example.

In this specification and the like, “voltage” and “potential” can be interchanged with each other as appropriate. Voltage refers to a potential difference from a reference potential, and when the reference potential is a ground voltage, for example, voltage can be replaced with potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be replaced with the term “conductive film” in some cases. As another example, the term “insulating film” can be replaced with the term “insulating layer” in some cases.

In this specification and the like, a switch has a function of controlling whether current flows or not by being in a conducting state (on state) or a non-conducting state (off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (which refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when represented by an equivalent circuit.

### REFERENCE NUMERALS

BGR: wiring, BGW: wiring, FN: node, MC: memory cell, RBL: wiring, RWL: wiring, VPRE: precharge voltage, WBL: wiring, WWL: wiring, 10: memory cell array, 11: memory cell

1. A semiconductor device comprising a memory cell comprising:
a first transistor and a second transistor,
wherein the first transistor comprises a gate electrode,
wherein the second transistor comprises a gate electrode and a back gate electrode,
wherein the gate electrode of the first transistor is electrically connected to a write word line supplying a write word signal,
wherein one of a source and a drain of the first transistor is electrically connected to a write bit line writing a potential corresponding to data,
wherein the other of the source and the drain of the first transistor is electrically connected to the gate electrode of the second transistor,
wherein the back gate electrode of the second transistor is electrically connected to a control signal line supplying a control signal controlling a threshold voltage of the second transistor,
wherein one of a source and a drain of the second transistor is electrically connected to a read word line supplying a read word signal,
wherein the other of the source and the drain of the second transistor is electrically connected to a read bit line reading the potential corresponding to the data,
wherein in the memory cell in a first data reading period when the memory cell is selected, a low level is supplied as the read word signal and a high level is supplied as the control signal, and
wherein in the memory cell in a second data reading period when the memory cell is not selected, a high level is supplied as the read word signal and a low level is supplied as the control signal.

2. The semiconductor device according to claim 1,
wherein each of the first transistor and the second transistor is an n-channel transistor.

3. The semiconductor device according to claim 1,
wherein each of the first transistor and the second transistor comprises a semiconductor layer comprising a channel formation region, and
wherein the semiconductor layer comprises an oxide semiconductor.

4. The semiconductor device according to claim 3,
wherein the oxide semiconductor comprises In, Ga, and Zn.

5. A method for driving a semiconductor device comprising a memory cell array comprising a memory cell comprising:
a first transistor in which a gate electrode is electrically connected to a write word line supplying a write word signal and one of a source and a drain is electrically connected to a write bit line writing a potential corresponding to data; and
a second transistor in which a gate electrode is electrically connected to the other of the source and the drain of the first transistor, a back gate electrode is electrically connected to a control signal line supplying a control signal controlling a threshold voltage of the second transistor, one of a source and a drain is electrically connected to a read word line supplying a read word signal, and the other of the source and the drain is electrically connected to a read bit line reading the potential corresponding to the data, the method comprising:
setting the read word signal to a low level and setting the control signal to a high level in the memory cell in a first data reading period when the memory cell is selected; and
setting the read word signal to a high level and setting the control signal to a low level in the memory cell in a second data reading period when the memory cell is not selected.

6. A semiconductor device comprising a memory cell comprising:
a first transistor and a second transistor,
wherein the first transistor comprises a gate electrode,
wherein the second transistor comprises a gate electrode and a back gate electrode,
wherein the gate electrode of the first transistor is electrically connected to a first wiring,
wherein one of a source and a drain of the first transistor is electrically connected to a second wiring writing a potential corresponding to data,
wherein the other of the source and the drain of the first transistor is electrically connected to the gate electrode of the second transistor,
wherein the back gate electrode of the second transistor is electrically connected to a third wiring,
wherein one of a source and a drain of the second transistor is electrically connected to a fourth wiring,
wherein the other of the source and the drain of the second transistor is electrically connected to a fifth wiring,
wherein in the memory cell in a first data reading period when the memory cell is selected, a low level is supplied to the fourth wiring and a high level is supplied to the third wiring, and
wherein in the memory cell in a second data reading period when the memory cell is not selected, a high level is supplied to the fourth wiring and a low level is supplied to the third wiring.

7. The semiconductor device according to claim 6,
wherein each of the first transistor and the second transistor is an n-channel transistor.

8. The semiconductor device according to claim 6,
wherein each of the first transistor and the second transistor comprises a semiconductor layer comprising a channel formation region, and
wherein the semiconductor layer comprises an oxide semiconductor.

9. The semiconductor device according to claim 8,
wherein the oxide semiconductor comprises In, Ga, and Zn.
